(19) United States
(12) Patent Application Publication
(10) Pub. No.: US 2014/0090976 A1
(43) Pub. Date: Apr. 3, 2014

(54) Ultrathin Film Solar Cells

(71) Applicant: Technion Research and Development Foundation, Haifa (IL)

(72) Inventors: Avner Rotschild, Haifa (IL); Hen Dotan, Moshav Olesh (IL); Ofer Kfir, Kibbutz Manara (IL); Elad Sharlin, Alfey Menashe (IL)

(73) Assignee: TECHNION RESEARCH AND DEVELOPMENT FOUNDATION LTD., Haifa (IL)

(21) Appl. No.: 14/116,210

(22) PCT Filed: May 10, 2012
(86) PCT No.: PCT/IL2012/050170

§ 371 Date: Nov. 7, 2013

Related U.S. Application Data
(60) Provisional application No. 61/484,545, filed on May 10, 2011.

(51) Int. Cl. H01G 9/20; H01L 31/0232; C25B 1/00; H01L 31/18

(52) U.S. Cl. CPC H01G 9/209; H01L 31/18; H01L 31/02327; C25B 1/003
USPC 204/267; 438/69; 136/254; 204/242

(57) ABSTRACT

A radiation conversion device is presented comprising at least one radiation conversion cell. The radiation conversion cell comprises a photo-absorber unit having a predetermined absorption spectrum for absorbing radiation of a certain wavelength range thereby converting the absorbed radiation into charge carriers, and at least partially reflective layer structure configured to be substantially reflective for said certain wavelength range. The photo-absorber unit and the at least partially reflective structure are configured to provide a desired refractive index profile across the radiation conversion cell with respect to said certain wavelength range and to define an optical cavity with respect to said certain wavelength range within the photo-absorber unit, thereby providing a desired interference condition for said certain wavelength range, thereby causing the radiation, absorbed by and propagating through said photo-absorber unit while being reflected from said at least partially reflective structure, to be effectively trapped within said photo-absorber unit.

### FIELD OF THE INVENTION

This invention is in the field of electromagnetic energy conversion, such as solar energy conversion, and relates to radiation conversion cells and devices utilizing such cells. The invention is particularly useful for photoelectrochemical and photovoltaic cells utilizing ultrathin film absorbers.

### BACKGROUND

Efficient conversion of solar energy to hydrogen via water photoelectrolysis is a long-standing challenge with a great promise for solar energy conversion and storage. Important advances in research and development (R&D) of semiconductor photoelectrodes for water splitting have been achieved in the last four decades since Fujishima & Honda's seminal report on photo-induced water splitting using TiO₂ photoanodes. Despite these advances no photoelectrochemical system for solar hydrogen production has met the technical requirements in terms of efficiency (≧10% solar to hydrogen conversion efficiency), durability (≧5000 h) and cost (≦3 USD per kg H₂). Numerous semiconductor photoelectrodes were examined, but most of them were ruled out due to poor stability or low efficiency. One of the most promising materials suitable to be used as photoanodes is α-Fe₂O₃ (Hematite), doped with tetravalent cations such as Si, Ti and Zr, or pentavalent cations such as Nb and Ta. This is because α-Fe₂O₃ was found to display an exceptional combination of visible light absorption, stability in aqueous solutions, non-toxicity, abundance and low cost.

With an energy band gap of ˜2.1 eV, α-Fe₂O₃ photoanodes can theoretically reach water photo-oxidation current densities as high as 12.6 mA cm⁻² under standard AM1.5G solar illumination conditions, which corresponds to a maximum solar to hydrogen conversion efficiency of 15.5% in a tandem cell configuration. However, because of low quantum efficiency, only a quarter of that limit has been achieved by the champion α-Fe₂O₃ photoanodes reported to date.

The low quantum efficiency of α-Fe₂O₃ photoanodes has been attributed to slow water oxidation kinetics and short diffusion length of the photogenerated minority carriers (holes). These deficiencies result in significant losses due to electron-hole recombination at the surface or in the bulk, respectively. Extensive research has been directed towards enhancing the water oxidation kinetics of α-Fe₂O₃ photoanodes using catalysts and reducing the bulk recombination loss by forming nanostructures of α-Fe₂O₃ in order to overcome the intrinsic tradeoff between light absorption and charge to collection efficiencies. Despite these efforts, state-of-the-art nanostructures of α-Fe₂O₃ photoanodes display charge separation yield around 20% while the injection yield of photogenerated holes that have reached the surface into the electrolyte exceeds 90% under sufficiently high anodic potentials, indicating that bulk recombination is the predominant loss mechanism limiting the performance of these photoanodes. A recent study on the oxygen evolution at α-Fe₂O₃ photoanodes confirms this observation. Thus, reducing bulk recombination is the key to improving the performance of α-Fe₂O₃ photoanodes—an important step towards efficient, stable and potentially inexpensive photoelectrochemical cells for solar energy conversion to hydrogen via solar-induced water splitting.

### GENERAL DESCRIPTION

There a need in the art in a novel approach for the configuration of radiation conversion systems, such as but not limited to photoelectrochemical cells, to improve the cell performance and enable various applications of such cells. The technique of the present invention utilizes an innovative approach for trapping light in ultrathin films of semiconducting photo-absorbers.

The conventional approach to overcome the intrinsic tradeoff between the light absorption and charge collection efficiencies of photoabsorbing electrode, such as α-Fe₂O₃ photoanodes, typically utilizes nanostructured relatively thick layers (layer thickness ≧400 nm) that absorb most of the light (at wavelengths shorter than 590 nm) while providing short distances to the surface of the photoabsorbing layer (up to a few tens of nanometers), thereby mitigating the bulk recombination loss. On top of the technological challenges in producing thick layers (typically between 0.5 and 1 μm) with optimized nanostructured morphologies, such conventional approach also presents intrinsic limitations connected with the high surface area of these electrodes which enhances the surface recombination loss and reduces the light intensity per unit surface area. This results in reducing the driving force for the water photo-oxidation reaction. Another disadvantage of the nanostructuring approach is connected with the high density of grain boundaries that are known to mitigate the performance of α-Fe₂O₃ photoanodes by enhancing recombination. Alternative routes are based on the use of ultrathin (≦50 nm) films on textured (patterned) substrates that increase their optical to density, or on achieving the same effect by using stacked multi-layers. However, similarly to the nanostructuring approach, these routes also enhance the surface area, resulting in similar deleterious effects.

It should be noted that on the broad scale, many semiconductor materials, and especially non-conventional ones (such as α-Fe₂O₃ and other metal oxides, chalcogenide and organic semiconductors, such as, for example, pyrite (Fe₂S) and Poly(3-hexylthiophene) (P3HT), demonstrate fast recombination of photo-generated minority charge carriers that gives rise to short (<100 nm) diffusion length of these carriers. As a result, the collection length of photo-generated minority charge carriers is small, often much smaller than the light absorption length (α⁻¹, where α is the absorption coefficient). This mismatch between the short charge collection and long light absorption lengths may result in low conversion efficiency of electromagnetic radiation (light) to other useful products such as electrical power (as in photovoltaic cells, PV cells) or chemical potential (as in photoelectrolysis cells and other types of photoelectrochemical cells). This tradeoff is particularly critical in compact (non-porous) films or layers of the photoactive absorber material.

The present invention provides a novel approach for constructing an electromagnetic (solar) radiation conversion system. More specifically, the technique of the invention is useful in conversion of solar radiation to provide energy for various processes, e.g. chemical processes as performed in e.g. photoelectrochemical cells. The invention is therefore described below with respect to this specific application. However, it should be understood that the principles of the invention as described below can advantageously be used in other types of radiation conversion systems, such as organic photovoltaic (PV) cells, intermediate band PV cells, and hot carrier PV cells. The technique of the invention pushes down the limits of light trapping in solar cells (photoelectrochemical and photovoltaic cells) from thin (>100 nm) to ultrathin (<100 nm) film photo-absorbers. In principle, light trapping in ultrathin films may be extremely useful in any type of solar cell wherein the absorption layer suffers from poor transport properties, in particular due to fast recombination and/or short diffusion length of charge carriers. The present invention solves this problem by allowing absorption of nearly all of the light energy in extremely thin layers, as described below.

Considering a photoelectrochemical cell, it may be used in various solar to powered electrochemical processes including, but not limited to, photoelectrolysis processes, such as water splitting for production of hydrogen, wastewater treatment by photo-oxidation of organic residues, and electrical power generation in photoelectrochemical solar cells. The present invention provides for boosting the efficiency of photoelectrodes, e.g. α-Fe₂O₃ photoanodes, and generally of photoactive semiconductor films (photo-absorbers), by trapping incident light within the photoelectrode (or photo-absorber) utilizing flat ultrathin films.

The radiation conversion device of the present invention utilizes the principles of light trapping within a light absorbing structure. This is implemented by providing a novel photo-absorber unit formed by a substantially anti-reflective light absorbing structure on top of a reflective (or at least partially reflective) structure (having one or more reflective interfaces); and a charge carriers' collection structure. It should be noted that the optically active semiconductor structure of the photo-absorber unit may directly interface the at least partially reflective structure, or the photo-absorber unit may include spacer layer(s) between the optically active semiconductor structure and the at least partially reflective structure. As will be described below, such spacer layers may include the charge carriers' collection structure. Typically, the device comprises one or more such photo-absorber units placed on a substrate, which may or may not be optically transparent.

In this connection, the following should be understood. Enhancing the amount of light absorbed in the active layer (photo-absorber) by light trapping mechanism can be generalized by understanding the required interference condition. With the above configuration of the radiation conversion device, and specifically for devices with the refractive indices of the photo-absorber unit (active structure), n_{active layer}, and its surroundings (e.g., water), n_{surroundings}, being such that n_{active layer}>n_{surroundings}, the required interference condition provides destructive interference of the over-all reflected light while providing constructive interference of the fields of the forward and backward propagating waves in the active structure, adjacent to the interface with the surrounding media, e.g., aqueous solution (water), collecting the photogenerated minority charge carriers. This constructive interference is a source of high absorption probability close to the interface, so the emerging charge carrier (e.g., holes in the case of photoanodes for water photo-oxidation in aqueous solution) can easily reach the charge carriers' collection structure (e.g., water). The optimum interference condition is to fully determined by this principle, because such effects as integration over multiple wavelengths, the finite probability for a charge carrier (hole) to reach the surface, etc. have been taken into account. Using this approach rather than looking for light-trapping alone, is advantageous for a better understanding of the system, and its crucial condition when n_{active layer}≦n_{surroundings}.

The above configuration of the radiation conversion device, when utilizing a photoelectrochemical cell, allows its use in a hybrid energy conversion system (a so-called tandem cell), and moreover enables such system to be integrated in a monolithic structure. Such a hybrid system comprises a photoelectrode unit being a photo-absorber unit, and utilizes a partially reflective or wavelength-selective reflective structure, placed on top of the light collecting surface of a typical photovoltaic (PV) cell. The partially reflective structure of the photoelectrochemical cell based device enables transmission of some of the collected incident light onto the photovoltaic cell. In the case of a wavelength-selective reflective structure, light of a first predetermined wavelength range is kept trapped within the layers of the photoelectrochemical cell while light of a second predetermined wavelength range is transmitted towards the photovoltaic cell. It should be noted that a wavelength-selective reflective structure may be formed as a wavelength selective reflector (filter) such as dielectric mirror or distributed Bragg reflector (DBR). Alternatively, a beamsplitter (such as prism or dichroic mirror) can be used to split the incident light into two beams of different spectral ranges, directing one beam to the photoelectrochemical cell and the other one to the photovoltaic cells.

In a simpler configuration, the photoelectrochemical cell and photovoltaic cell may be placed one above the other, or one next to the other such that both face the incident light, thereby reducing the need to redirect or deflect the collected light.

It should be noted that in such hybrid photovoltaic/photoelectrochemical device, the photovoltaic cell may provide electrical power to the photoelectrochemical cell. To this end, the electrical power generated in the photovoltaic cell may be divided into two parts, where one part is used for powering its associated photoelectrochemical cell and the other part is used for providing electrical power for any other purpose.

Thus, a radiation conversion device of the present invention includes a photoelectrode unit (photo-absorber unit) comprising a photoactive semiconductor layer structure, at least partially reflective layer structure, and a charge carriers' collector structure. In some embodiments, the photoactive semiconductor layer structure interfaces with the at least partially reflective layer structure, in which case the charge carriers' collector structure (e.g. aqueous solution) is at the other side of the photoactive semiconductor layer structure. In some other embodiments, charge carriers' collector structure (e.g. transparent electrode such as FTO, ITO or AZO, instead of the aqueous solution in the photoelectrochemical cell) is located between the photoactive semiconductor layer structure and the reflective layer structure.

In some embodiments, the radiation conversion device further includes a photovoltaic unit, which is located in the optical path of incident light, e.g. upstream or downstream of the above photoelectrode unit, or adjacent thereto.

The material compositions, optical properties and geometrical parameters of the photo-absorber unit and the at least partially reflective structure are selected to provide a desired refractive index profile across the device with respect to a certain wavelength range which should undergo energy conversion, while with as thin as possible photo absorber unit providing as much as possibly reduced recombination of photo generated charge carriers. For a given photo-absorber unit, the material compositions and geometrical parameters of the at least partially reflective structure are selected to provide high stability of the entire device when being manufactured and when being operated (e.g. temperature conditions, corrosion, etc.). The at least partially reflective structure is selected to be substantially non-absorbing for the wavelength range to be converted by the photo-absorber unit. As for the interface between the photo-absorber unit and the charge carriers' collection structure, it provides for selective collection of either electrons or holes, but not both of them.

In some embodiments, the configuration is such that the appropriate selection of the above parameters/conditions, an optical cavity (resonance cavity) is crated within the photo-absorber unit, allowing the above described interference condition, i.e. over-all destructive interference outside the photo-absorber unit and constructive interference within the photo-absorber unit. In some other embodiments, such condition is achieved by configuring the device with multiple reflections of light while propagating within the device, thereby increasing light absorption.

The invented approach provides for the radiation conversion device with a photo-absorber unit (with or without the “spacer”) of a thickness substantially not exceeding quarter of the weighted average wavelength of absorption.

Thus, according to one broad aspect of the present invention, there is provided a radiation conversion device comprising at least one radiation conversion cell. The radiation conversion cell comprises: a photo-absorber unit having a predetermined absorption spectrum for absorbing radiation of a certain wavelength range thereby converting the absorbed radiation into charge carriers, and at least partially reflective layer structure configured to be substantially reflective for said certain wavelength range. The photo-absorber unit and the at least partially reflective structure are configured to provide a desired refractive index profile across the radiation conversion cell with respect to said certain wavelength range and to define an optical cavity with respect to said certain wavelength range within the photo-absorber unit, thereby providing a desired interference condition for said certain wavelength range, thereby causing the radiation, absorbed by and propagating through said photo-absorber unit while being reflected from said at least partially reflective structure, to be effectively trapped within said photo-absorber unit.

The photo-absorber unit comprises an optically active semiconductor structure having predetermined material composition and thickness being selected to operate as an anti-reflective structure for said certain wavelength range corresponding to maximal absorption of incident electromagnetic radiation by said semiconductor structure.

It should be noted that the semiconductor photo-absorber typically acts as an electrode or a part thereof; the terms “photo-absorber” and “electrode” or “photoelectrode” relating to said semiconductor structure are used herein interchangeably and should be interpreted in the broad meaning as relating to the photo-active semiconductor structure/unit as describe above.

The at least partially reflective structure is a single- or multi-layer structure. In some embodiments, the at least partially reflective structure is configured as a wavelength-selective reflector.

The photo-absorber unit may comprise the optically active semiconductor structure and an electrode structure which is substantially transparent for said certain wavelength range. The transparent electrode interfaces the at least partially reflective structure on one side thereof and the optically active semiconductor structure at the opposite side thereof.

Preferably, the photo-absorber unit has a thickness substantially not exceeding λ̅/4n, where λ̅ is a weighted average wavelength of said certain wavelength range and n is an effective refractive index of said optically active semiconductor structure.

The photo-absorber unit may have a thickness smaller than a recombination length for photo-generated charge carriers in said optically active semiconductor structure.

The at least partially reflective layer may be in the form of a dielectric or dichroic mirror structure.

The at least partially reflective structure comprises a substrate having the at least partially reflective coating comprising one of the following material compositions: silver-gold and silver-platinum alloys.

In some embodiments, the optically active semiconductor structure comprises an α-Fe₂O₃ layer. The at least partially reflective structure may comprise a substrate having the at least partially reflective coating comprising one of the following material compositions: silver-gold composition with 5% to 15% gold; and silver-platinum alloys with 10% to 22% platinum.

The device may be configured as a photoelectrochemical device, e.g. for photoelectrolysis of water.

The device may comprise at least two radiation conversion cells configured to face one another by their radiation absorbing layers with a certain angle to allow incident electromagnetic radiation reflected from one of the cells to propagate towards and be absorbed by the other cell. The at least two radiation conversion cells may be arranged in a V shape configuration, said certain angle ranging between 30 and 90 degrees.

In some embodiments, the device may comprise a photovoltaic cell located below the at least partially reflective structure. In this case, said at least partially reflective structure is configured to reflect light component of said certain wavelength range while transmitting light components with a different wavelength range corresponding to the absorption spectrum of said photovoltaic cell.

In some embodiments, the device may comprise a partially transparent photovoltaic cell located on top of the photo-absorber unit. In this case, the partially to transparent photovoltaic cell is configured to transmit light components of said certain wavelength range while absorbing a different wavelength range.

The semiconductor photo-absorber structure has predetermined material composition, layer structure and thickness selected to generate constructive interference between forward and backward propagating waves inside the photo-absorber structure. Thus, the semiconductor structure operates, essentially, as an anti-reflective layer for a predetermined wavelength range, thereby achieving maximal absorption of the incident light by said semiconductor photo-absorber. In case the photoelectrode unit is used in the above-mentioned hybrid device being placed on top of a photovoltaic cell, the device provides maximal absorption of one range of wavelengths of the incident light in the semiconductor photo-absorber (photoelectrode) and another range of wavelengths of said incident light in the photovoltaic cell.

It should be understood that the light trapping occurs because the parameters of the structures (e.g. thickness, refractive indices) are appropriately selected to cause constructive interference within the semiconductor photo-absorber and destructive interference outside of it. The destructive interference occurs between the first order reflected beam and higher order reflected beams, reflected back and forth between the reflective layer and the light collection interface of the semiconductor structure (collecting light from surrounding, e.g. PV cell, aqueous solution, etc.). This increases the light absorbance in the semiconductor photo-absorber layer and thus improves the device performance.

For example, when configured for light trapping of normal incident illumination, the semiconductor photo-absorber layer/structure is configured to have a thickness of approximately λ̅/4n, where n is the refractive index of the semiconductor light absorbing layer (the photo-absorber), at the weighted average wavelength λ̅, and λ̅ is the weighted average wavelength between the shortest wavelength in the incident electromagnetic radiation (λₘᵢₙ) and the absorption edge of semiconductor photo-absorber material (λₘₐₓ), weighted by the product of the spectral photon flux distribution of the incident electromagnetic radiation, I⁰_{λ}(λ), and the absorption coefficient of the semiconductor photo-absorber material, α(λ):

$$\overline{λ} = \frac{{\int }_{{λ}_{min}}^{{λ}_{max}} λ {I}_{λ}^{0} ( λ ) α ( λ ) d λ}{{\int }_{{λ}_{min}}^{{λ}_{max}} {I}_{λ}^{0} ( λ ) α ( λ ) d λ} \qquad ( eqn . 1 )$$

where λ is the wavelength of the electromagnetic radiation in air (n=1). The absorption edge of semiconductor photo-absorber material (λₘₐₓ) is typically determined by the bandgap energy of semiconductor (E_{g}). The value of λₘₐₓ may be determined according to the formula λₘₐₓ=1240/E_{g} with λₘₐₓ given in nanometers (nm) and E_{g} in electron-volts (eV).

As described above, photoelectrochemical cells configured according to the present invention may be efficiently used for water splitting process. In this, or similar applications, the semiconductor photo-absorber layer preferably comprises high absorbing semiconductor material having high stability in aqueous environment. For example, the semiconductor electrode layer may be made of α-Fe₂O₃, WO₃, TiO₂, SrTiO₃, Cu₂O, TaON, BiVO₄, ZnO, GaN, (GaN)₁₋ₓ(ZnO)ₓ, CdS, or other semiconductor materials with a bandgap energy between 1.5 and 3.2 eV that are sufficiently stable in aqueous solutions (in a certain pH and potential window in which water oxidation or reduction occurs).

The reflective layer structure (being at least partially reflective) may be a single- or multi-layer structure. As indicated above, according to some embodiments, a transparent electrically conducting layer (e.g., TiO₂, SnO₂, Nb-doped TiO₂, Nb-doped SnO₂, F-doped SnO₂, Sb-doped SnO₂, Nb₂O₅, SrTiO₃) is used, being formed on top of a reflective (at least partially reflective) layer and interfacing with said semiconductor photo-absorber layer. Such conductive transparent layer is typically configured to mitigate oxidization and corrosion of the material of the reflective layer, and also to reduce backward injection of minority charge carriers from the semiconductor photo-absorber to the current collector at the substrate.

According to some other embodiments, the partially reflective layer structure comprises a multilayer structure comprising transparent materials having different refractive indices (e.g., a series of layers of SiO₂ and TiO₂ or SiO₂ and SnO₂). The multilayer structure thus generally has a certain refractive index profile and that of reflection coefficient to provide together a dielectric mirror (also known as distributed Bragg reflector or DBR) that reflects part of the incident light spectrum while transmitting other part of the spectrum. In the configuration of the hybrid cell/hybrid device (including photo-absorbing unit and a photovoltaic cell) according to the present invention, the reflected light components may be reflected back to the semiconductor photo-absorber layer while the transmitted light components may reach the photovoltaic cell.

According to some embodiments of the present invention, at least two photo-absorber units are arranged together, such that the radiation absorbing layers (semiconductor photo-absorbers) are facing each other, e.g. in a V shape configuration. The photo absorber units are arranged to allow light reflected from one of the units to be absorbed by one of the other units. The angle between the photo-absorber units is determined to induce multiple reflections back and forth between them, such that light components reflected from one unit (back-reflected photons) are trapped by one of the other units. This may be achieved by appropriately selecting the angle between the units in accordance with the refractive indices of the semiconductor photo absorbers of the units and the reflection coefficient of each unit as a whole. Typically the angle between each two units in this configuration varies between 30° and 90°.

According to yet another broad aspect of the invention, there is provided a method for forming a radiation conversion device. The method comprises: applying an at least partially reflective coating layer structure on a substrate; applying a photo-absorber structure comprising an optically active semiconductor of a predetermined thickness and a predetermined absorption spectrum on top of said at least partially reflective coating, said predetermined thickness being selected in accordance with refractive index profile along the device to thereby provide an optical cavity providing a desired interference condition for said certain wavelength range within said photo-absorber structure thereby causing light of a wavelength range within said predetermined absorption spectrum impinging onto said photo-absorber structure to be trapped within said optically active semiconductor

According to yet another broad aspect of the invention there is provided a method for forming a photoelectrochemical-photovoltaic tandem cell, the method comprising: placing at least one partially transparent photovoltaic cell (such as dye solar cells or amorphous silicon thin film PV cells on transparent substrates) directly above the photoelectrochemical cell as described above, the photoelectrochemical cell being configured for light trapping of wavelengths absorbed by its photoelectrode and the partially transparent photovoltaic cell being configured to absorb other wavelengths. The photoelectrode of the photoelectrochemical cell is placed on a reflective (or at least partially reflective) substrate, and its thickness is predetermined to trap light of wavelengths absorbed by the photoelectrode material by inducing constructive interference inside the photoelectrode.

In yet another broad aspect of the invention there is provided a method for forming a photoelectrochemical-photovoltaic tandem cell, the method comprising: placing the photoelectrochemical cell side by side with the photovoltaic cells, both facing the radiation source.

In yet another broad aspect of the invention there is provided a method for forming a photoelectrochemical-photovoltaic tandem cell, utilizing a wavelength-selective beamsplitter (such as prism or dichroic mirror) that splits incident light into two or more spectral ranges, deflecting them to different directions. For instance, a dichroic mirror placed at some inclination angle to the incident beam passes one spectral range directly through the mirror in the same direction of the incident beam while deflecting the another spectral range to another direction. The photovoltaic cell and photoelectrochemical cell are placed in the directions of the two partial beams, facing each beam to achieve optimal light absorption for wavelengths below the absorption edges of the photo-active layers in these cells.

As indicated above, although the present application is exemplified below mainly for a photoelectrochemical cell, the invention should not be limited to these specific embodiments. The light trapping approach of the invention can be used in solar energy conversion systems of other types as well.

### BRIEF DESCRIPTION OF THE DRAWINGS

In order to understand the invention and to see how it may be carried out in practice, embodiments will now be described, by way of non-limiting example only, with reference to the accompanying drawings, in which:

FIG. 1A shows charge separation and collection yield of Ti-doped (1 at %) α-Fe₂O₃ dense films as a function of the film thicknesses for different applied potentials;

FIG. 1B shows the absorption spectra for α-Fe₂O₃ dense films of different thicknesses;

FIG. 2 schematically illustrates a photoanode structure according to the present invention;

FIGS. 3A-3F show calculated photon flux profiles as a function of film thickness and depth from the surface into the film for α-Fe₂O₃ films on ideally reflective (A), transparent (B), and metalized substrates coated with silver (C), aluminum (D), gold (E) or platinum (F) back-reflectors;

FIG. 4 shows absorbed photon flux and the corresponding photogenerated current density as a function of film thickness for specimens comprising Ti-doped α-Fe₂O₃ films on reflective (R=1), partially reflective (Ag, Al, Au, or Pt coated) and transparent (R=0) substrates;

FIG. 5 shows minority carriers separation and collection probability profile inside the film as a function of film thickness and depth;

FIGS. 6A-6F show calculated photocurrent density per unit volume profiles as a function of film thickness and depth for α-Fe₂O₃ films on ideally reflective (A), transparent (B), and metalized substrates coated with silver (C), aluminum (D), gold (E) or platinum (F);

FIG. 7 shows calculated photocurrent density as a function of film thickness for α-Fe₂O₃ films on different substrates under ideal forward injection;

FIG. 8 show photocurrent density measured for Ti-doped α-Fe₂O₃ films of different thicknesses on platinized substrates;

FIGS. 9 and 10 show stability tests for silver (100% Ag) and silver-gold alloys in 1M NaOH aqueous solution;

FIGS. 11 and 12 show reflectivity measurements for platinized wafers and wafers coated with silver-gold (with 5% or 15% gold) and silver-platinum alloys (with 10% or 22% platinum) and comparison of the reflectivity of metal coated substrates (coated with Pt, Ag, Ag—Au alloys with 5 or 15% Au, and Ag—Pt alloys with 10 or 22% Pt) before and after heating to 450° C. in oxygen;

FIG. 13 illustrates schematically a photoanode unit configured with silver-gold alloy according to the present invention;

FIG. 14 shows photoelectrochemical test of a photoanode device of FIG. 13;

FIG. 15 shows schematic illustration of a hybrid system comprising photoelectrochemical cell in tandem with photovoltaic cell with a dichroic mirror serving as a beam splitter splitting the incident light into two spectral ranges one being directed to the photoelectrochemical cell and the other to the photovoltaic cell;

FIG. 16 shows experimental results for the water photo-oxidation current density obtained with a thin (˜30-40 nm) α-Fe₂O₃ film on platinized silica wafer in tandem with a Si photovoltaic cell with a dichroic mirror serving as a beam splitter (that is in the hybrid system configuration depicted in FIG. 15);

FIG. 17 shows schematic illustration of a monolithic system comprising photoelectrode in tandem with photovoltaic cell with a dielectric mirror serving as a beam splitter splitting the incident sunlight into two spectral ranges one is reflected back to the photoelectrode and the other passing through to the photovoltaic cell.

FIG. 18 exemplifies a monolithic hybrid system including a dielectric reflective layer structure between the photoelectrode and the PV cell;

FIG. 19 exemplifies another embodiment of the invention, utilizing a V-shape cell with two photoelectrodes facing each other at an angle θ;

FIG. 20 shows calculated water photo-oxidation current density for a V-shape system, as illustrated in FIG. 19, comprising two monolithic cells as illustrated schematically in FIG. 18.

FIG. 21 is schematic illustration of cell design for light trapping in ultrathin absorbing films of thickness below the λ/4n limit;

FIG. 22 illustrates expected optical performance (in terms of the calculated absorbed current density) for the cells as illustrated in FIG. 21 (with Ag as the reflective coating (back reflector)) as a function of the thickness of the α-Fe₂O₃ absorbing layer (d_{ETA}) and the thickness of the transparent SnO₂ electrode (d_{TCO});

FIG. 23 illustrates expected photoelectrochemical performance (in terms of the calculated water photo-oxidation current density) for the cells as illustrated in FIG. 21 (with Ag as the reflective coating, i.e., back reflector), as a function of the thickness of the α-Fe₂O₃ absorbing layer (d_{ETA}) and the thickness of the transparent SnO₂ electrode (d_{T}co);

FIG. 24 is schematic illustration of V-shape cell with two photoelectrodes as illustrated in FIG. 21 facing each other at an angle θ;

FIG. 25 illustrates ray traces in a V shape cell of FIG. 24 with an angle (θ) of 45° between the two photoelectrodes;

FIG. 26 shows expected optical performance (in terms of the calculated absorbed current density) for the V shape cell as illustrated in FIG. 24 with an angle (θ) of 90° between the two photoelectrodes, Ag reflective coating (back reflector), α-Fe₂O₃ photo-absorber layer (ETA) and SnO₂ transparent electrode layer (TCO);

FIG. 27 shows expected photoelectrochemical performance (in terms of the calculated water photo-oxidation current density) for the V shape cell as illustrated in FIG. 24 with an angle (θ) of 90° between the two photoelectrodes, Ag reflective coating (back reflector), α-Fe₂O₃ photo-absorber layer (ETA) and SnO₂ transparent electrode layer (TCO);

FIG. 28 shows expected optical performance (in terms of the calculated absorbed current density) for the V shape cell as illustrated in FIG. 24 with an angle (θ) of 60° between the two photoelectrodes, Ag reflective coating (back reflector), α-Fe₂O₃ photo-absorber layer (ETA) and SnO₂ transparent electrode layer (TCO);

FIG. 29 shows expected photoelectrochemical performance (in terms of the calculated water photo-oxidation current density) for the V shape cell as illustrated in FIG. 24 with an angle (θ) of 60° between the two photoelectrodes, Ag reflective coating (back reflector), α-Fe₂O₃ photo-absorber layer (ETA) and SnO₂ transparent electrode layer (TCO);

FIG. 30 shows expected optical performance (in terms of the calculated absorbed current density) for the V shape cell as illustrated in FIG. 24 with an angle (θ) of 45° between the two photoelectrodes, Ag reflective coating (back reflector), α-Fe₂O₃ photo-absorber layer (ETA) and SnO₂ transparent electrode layer (TCO);

FIG. 31 shows expected photoelectrochemical performance (in terms of the calculated water photo-oxidation current density) for the V shape cell as illustrated in FIG. 24 with an angle (θ) of 45° between the two photoelectrodes, Ag reflective coating (back reflector), α-Fe₂O₃ photo-absorber layer (ETA) and SnO₂ transparent electrode layer (TCO);

FIG. 32 illustrates photoelectrochemical test of a V shape cell with an angle (θ) of 90° between the two electrodes, with each electrode having the same configuration as the one in FIG. 13; and

FIG. 33 is schematic illustration of a tandem cell with semi-transparent PV cell to on top of a photoelectrochemical cell (or a second PV cell). The two cells absorb different spectral regions of the solar spectrum, and the second cell (the one at the bottom) employs one of the light trapping strategies described in this invention (e.g., the ones illustrated in FIG. 2, 13, 17, 19, 21, or 24).

### DETAILED DESCRIPTION OF EMBODIMENTS

As indicated above, the present invention provides for a novel approach for use in solar radiation conversion systems, configured to convert optical radiation to electrical and/or chemical energy. The system of the present invention may be used for photoelectrolysis of water utilizing α-Fe₂O₃ photoanodes and is generally described herein in this connection. However, it should be understood that the use of α-Fe₂O₃ photoanodes is described to provide a concrete example and the technique of the invention is not limited to this specific material selection. As described above the technique of the present invention can be used with various semiconductor material compositions, and relates to the configuration of the photo absorber structure and to photoelectric or photoelectrochemical cells. The semiconductors suitable to be used in the device of the invention can be covalent (Si, Ge etc.), III-V (GaAs), II-VI (CdTe), oxide (α-Fe₂O₃ etc.), organic (P3HT etc.), chalcogenide (CdS etc.), or other photo-absorbing semiconductors.

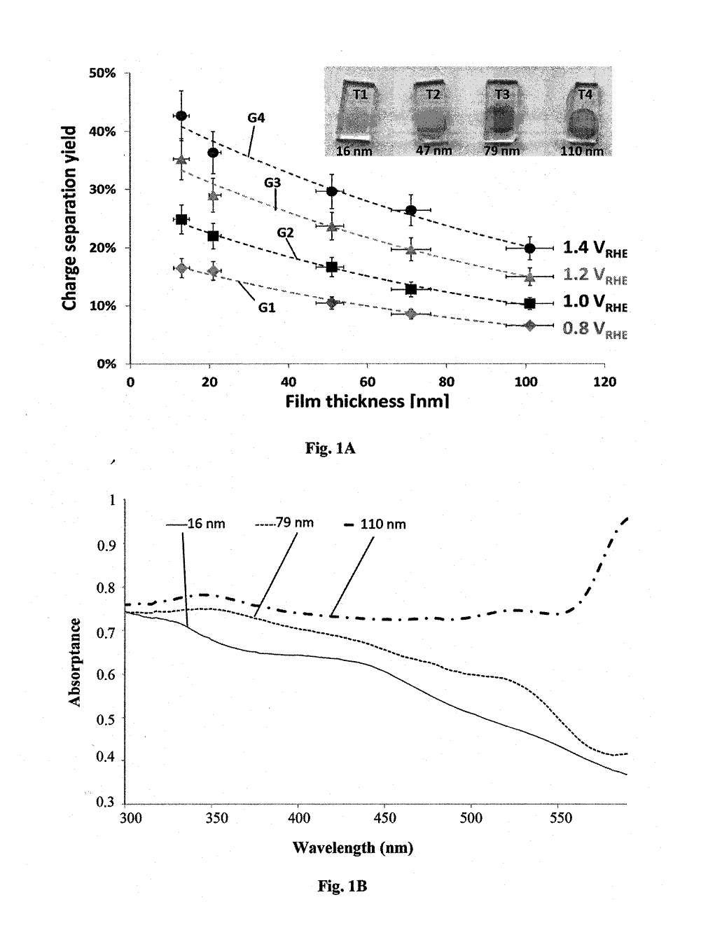

To this end, the rationale for using ultrathin α-Fe₂O₃ photoanodes stems from their high charge collection efficiency compared to their nanostructured thick layer counterparts. This is demonstrated in FIG. 1A showing charge separation and collection yield of dense α-Fe₂O₃ films as a function of the film thickness (ranging from 16 to 110 nm) and example images of the thin films T1-T4. The α-Fe₂O₃ films are doped with Ti (1 at %) in order to enhance their electronic conductivity, and deposited by pulsed laser deposition (PLD) on fluorinated tin oxide (FTO) coated glass substrates. FIG. 1B shows three graphs corresponding to absorption spectra of dense α-Fe₂O₃ films of 16 nm, 79 nm and 110 nm thicknesses respectively.

FIG. 1A shows four graphs G1-G4 corresponding to four different applied potentials ranging between 0.8 and 1.4 volts against the reversible hydrogen electrode (V_{RHE}), respectively. As shown, the charge separation and collection yield increases to with decreasing the film thickness, reaching 43±4% for the thinnest film (having thickness of 16±2 nm). This value is twice as high as the maximal yield obtained with state-of-the-art nanostructured α-Fe₂O₃ thick layers (400-700 nm). This result demonstrates the potential advantage of dense ultrathin films of high crystalline quality, as typically obtained by physical vapor deposition (PVD) methods such as PLD or reactive sputtering, compared to nanostructured thick layers obtained by chemical deposition routes. However, the optical density (light absorbance) of such ultrathin films is very small, as can be seen in the pictures T1-T4 of the thin films. The thinnest film T1, having the highest charge separation yield, is nearly translucent because it is much thinner than the penetration depth of visible light in α-Fe₂O₃ (e.g., α⁻¹=333 nm at λ=550 nm). Thus, effective utilization of ultrathin films as photoelectrodes for solar light harvesting and conversion to chemical potential or electrical power requires special optical schemes in order to enhance light absorbance (i.e. to increase the probability of light-matter interaction in sub-wavelength structures). This is required in order to boost light absorption in the photoelectrode structure. The standard method for enhancing light absorption in thin film solar cells by using textured substrates that scatter light randomly multiple times inside several micrometers thick layers, thereby increasing the optical path length in the absorber, is unsuitable for ultrathin films of tens of nanometers which is only a fraction of the wavelength of the absorbed light.

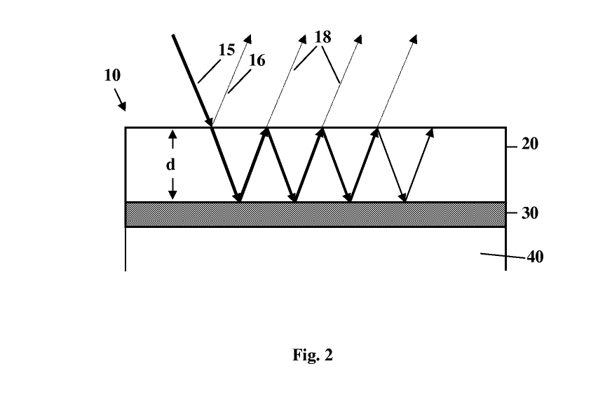

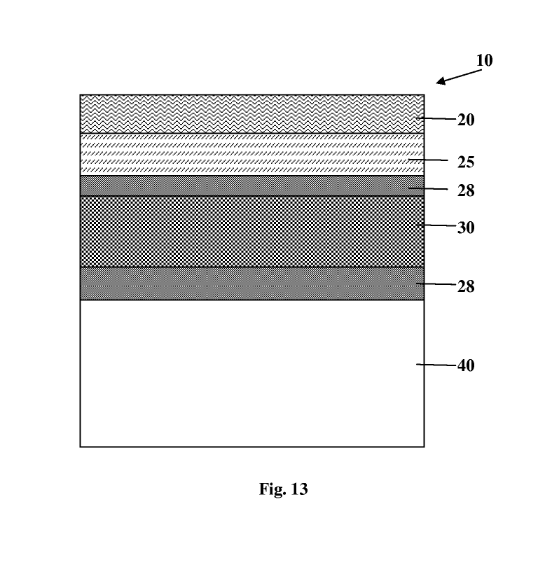

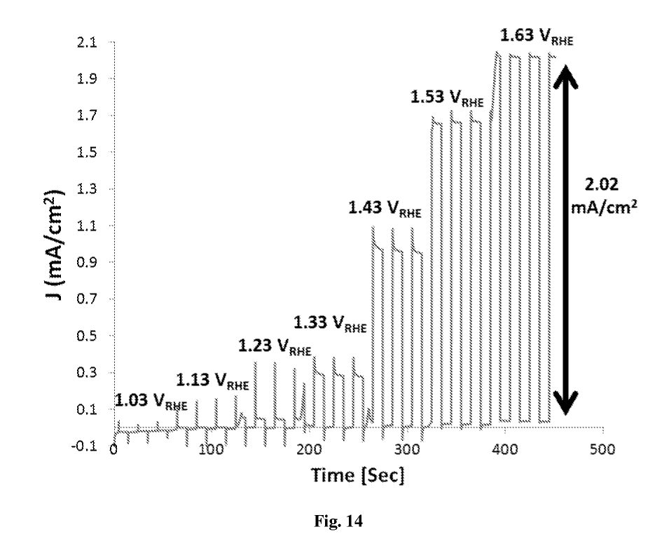

Thus the present invention provides a technique for effective light trapping in ultrathin films (i.e. substantially up to a few hundreds of nanometers, preferably not exceeding 100 nanometers). According to the present invention, the ultrathin photo-absorber films are placed on (or attached to) a reflective structure (at least partially reflective) and configured to substantially operate as an optical cavity that induces constructive interference between forward and backward propagating waves (due to resonance condition) within the thin film semiconductor photo-absorber (e.g. α-Fe₂O₃ photoanode) while absorbing the incident light. The light trapping technique of the present invention relies on the wave-nature of light propagating in sub-wavelength structures which is essentially different in nature and resulted device performance from that of statistical rays optics and scattering optics as known from different techniques for trapping light in thin film solar cells. As indicated above, the optically active semiconductor structure of the photo-absorber unit (i.e. photo-absorber film) may directly interface the at least partially reflective structure as described with reference to to FIGS. 2, 17, 19, or a spacer may be provided between the optically active semiconductor structure and the at least partially reflective structure configured for the charge carriers collection as will be described below with reference to FIGS. 13, 18, 21, 24, 33.

The present invention utilizes light trapping in ultrathin films, typically of semiconductor photo-absorbers (a.k.a. extremely thin absorbers or ETA), without increasing the surface area of the films. This can be achieved by providing a configuration of the thin films as optical cavities and thus providing light trapping therein. Photons of the trapped light are located within the thin film for relatively longer time periods and thus the probability for absorbance increases. For example, the ultrathin absorbing films are place on (or attached to) reflective substrate which serves as current collector and back reflector, giving rise to interference between the forward and backward propagating waves.

Reference is made to FIG. 2 illustrating schematically an example of the radiation conversion device 10 of the invention including a thin film photo absorbing layer 20 (constituting a photo-absorber unit or optically active semiconductor structure) placed on a reflective (at least partially) structure 30 (this may be a coating on a substrate) which defines one or multiple reflective interfaces. Unlike the conventional photoelectrode design using transparent FTO-coated glass substrates wherein the incident light has only one pass through the photoelectrode, the design of the present invention is configured to reflect the incident light back and forth between the bottom and top interfaces of the photoelectrode, thereby boosting light absorption by increasing the photon lifetime in the film, reaching maximum absorption in the cavity resonance modes. The underlying physics is illustrated in FIG. 2 showing the trajectories of an incident light ray 15 penetrating the light absorbing film 20 and propagates back and forth 25 within the absorbing thin film. The thickness d of the film is configured in accordance with the refractive index thereof and the refractive indices of the surrounding and reflective parameters of the reflective layer 30, such that incident light interfere destructively outside of the absorbing film 20 while constructively interfere within the absorbing film 20. The interference characteristics of incident light are created due to the phase shifts (4) of the reflected beams with respect to the incident beam. The photoanode unit 10 is appropriately designed to provide that the high order reflections 18 are all in phase (i.e. Δφ=2π×m, where m is an integer number) with the incident beam 15, and out-of-phase with the first-order reflection 16, which is in it phase shift with respect to the incident beam 15. These phase relations give rise to destructive interference of the back reflected beam, attenuating the intensity of the reflected light components. The incident light 15 is therefore unable to propagate forward into the substrate because of the back reflector 30, and the backward reflections undergo destructive interference, the light intensity is therefore trapped inside the photo-absorbing film 20.

In order to generate the desired interference relations described above the thickness d of the photo-absorber film 20 is preferably configured to be approximately equal to a quarter of the wavelength (λ) of the incident light that (generally, at least a part thereof) is absorbed in the photo-absorber material (i.e., d≈λ/4n where n is the refractive index of the film 20 at the same wavelength λ).

It should be noted that this thickness calculation, defining a quarter wave thickness, corresponds to the case of direct incidence of the collected light (normal incident light) and to collection of monochromatic light at certain wavelength λ. However, the light absorbing film 20 may be similarly configured (e.g. by determining the thickness) for efficient light collection and trapping of polychromatic illumination from various incident angles. Generalization of the above calculation to provide light trapping for incident light at a range of wavelengths and different incident angles will be described further below. Utilizing polychromatic illumination, the optimal thickness is to be determined in accordance with a weighted average wavelength, λ̅, as defined by eqn. (1) above. To this end, the optimal thickness of the photo-absorber film 20 is determined taking into account, inter alia, such parameters/condition as phase shift at the photoelectrode/back-reflector interface (which may be it or shifted therefrom), oblique or normal incidence of light to be converted, and charge transport considerations (separation and collection of minority carriers).

It should also be noted, and will be described further below, that further generalization of the resonance condition can provide the desired constructive and destructive interference relations by the photo-absorber film 20 for different angles of incidence. The general configuration may utilize a multi-layer stack creating multiple reflections from multiple interfaces. Additionally, the design of the photoelectrode and in particular of the photo-absorber film 20 typically considers the regions where the photons are best absorbed to thereby generate optimal efficiency. To this end the following methodology for calculating the optimal thickness of the photo-absorber film 20 is described utilizing α-Fe₂O₃ photo-absorber, however it should be understood that other materials may be use for the photo-absorbing film.

Strictly speaking the quarter-wave condition applies for monochromatic light. However, as described above, the technique of the present invention is operable with any incident electromagnetic radiation, and typically under sunlight, with a broad spectral distribution. Therefore, the film thickness for trapping polychromatic radiation (e.g., sunlight) is determined in accordance with the spectral range between the absorption edge of the semiconductor photo-absorber film (in this example λₘₐₓ=590 nm for α-Fe₂O₃) and the falloff of the optical irradiance spectrum (λₘᵢₙ=300 nm for solar radiation) as described in eqn. 1 above.

Additionally, the film thickness d may also be determined according to the location where the collected photons are absorbed (i.e., at what distance from the surface of the film). The inventors of the present invention have found that the optimal thickness can be calculated by integrating the product of the photogenerated charge carriers distribution profile and the charge separation and collection probability profile, with the integration performed over the entire film thickness and over the solar irradiance spectrum (for wavelengths shorter than the absorption edge of the photo-absorber film). The calculation includes scaling the distribution with the light intensity profile inside the photo-absorber film, and the charge separation and collection probability profile to determine the photocurrent density as a function of film thickness, to thereby find the optimal thickness for a given photo-absorber material on a given back-reflector. This calculation is described below with reference to α-Fe₂O₃ photoanodes for water photo-oxidation. However, the principles underlying the methodology are common to other photoelectrodes and therefore it can be readily extended to other systems.

The calculation of the light intensity distribution inside the film relies on the plane-wave solution of Maxwell's electromagnetic wave equation being tailored to fit the boundary conditions of the problem with incident (solar) radiation. The boundary conditions were selected to describe the configuration of the photoelectrode described above with reference to FIG. 2.

The case of normal incidence on ideally reflective substrates (with a reflectance R, of 100% at all wavelengths that may be absorbed by the photo-absorber film) is described by eqn. 2 obtained for the spectral photon flux I_{λ}(x,d,λ) (defined as the number of photons per unit time, unit area and unit wavelength) inside a film of thickness d:

$$\begin{matrix}{I}_{λ} ( x , d , λ ) = {I}_{λ}^{0} ( λ ) T ( λ , d ) {\vert {e}^{\frac{2 π i}{λ} [ {n}_{2} ( λ ) + {iκ}_{2} ( λ ) ] x} - {e}^{\frac{2 π i}{λ} [ {n}_{2} ( λ ) + {iκ}_{2} ( λ ) ] ( 2 d - x )} \vert}^{2} \\ where & ( eqn . 2 ) \\ T ( λ , d ) = \frac{{n}_{2} ( λ )}{{n}_{1} ( λ )} {\vert \frac{2 {n}_{1} ( λ )}{{n}_{1} ( λ ) + {n}_{2} ( λ ) {iκ}_{2} ( λ ) + [ {n}_{1} ( λ ) - {n}_{2} ( λ ) - {iκ}_{2} ( λ ) ] {e}^{\frac{4 iπ}{λ} ( {n}_{2} ( λ ) + {iκ}_{2} ( λ ) ) d}} \vert}^{2} & ( eqn . 2 A )\end{matrix}$$

is the transmissivity at the front surface (at x=0), I_{λ}⁰(λ) is the incident spectral photon flux, n and κ are the refractive and attenuation indices of the respective media (designated by subscript 1 for the surrounding (e.g. water) and 2 for the photo-absorber thin film, (e.g. α-Fe₂O₃) and x is a measure of the location within the layer (along an axis perpendicular to the interface between layers, with the front (light collection) surface of the photo-absorber film at x=0 and the reflective surface is at x=d), and i is the imaginary unit, i=(−1)^{1/2}.

In the configuration with no reflective layer 30 and the completely transparent substrate 40 (R=0 at all wavelengths that may be absorbed by the photo-absorber film) the photon flux within the photo-absorber 20 is described by equation 3:

$$\begin{matrix}{I}_{λ} ( x , λ ) = {I}_{λ}^{0} ( λ ) T ( λ ) {e}^{- {α}_{2} ( λ ) x} \\ where & ( eqn . 3 ) \\ T ( λ ) = \frac{{n}_{2} ( λ )}{{n}_{1} ( λ )} {\vert \frac{2 {n}_{1} ( λ )}{{n}_{1} ( λ ) + {n}_{2} ( λ ) + {iκ}_{2} ( λ )} \vert}^{2} & ( eqn . 3 A )\end{matrix}$$

where α(λ)=4πκ(λ)/λ, is the absorption coefficient of the photo-absorber 20.

The general case, where α partially-reflective (0<R<1) layer 30 is located under the photo-absorber 20, the summation, I(x, λ)=n₂(λ)|ΣEᵢ(x,t,λ)|² where Eᵢ is the electromagnetic field in the i'th pass of a light component through the film, is used to obtain the following expression describing the photon flux:

$$\begin{matrix}{I}_{λ} ( x , λ , d , {\hat{r}}_{23} ) = {I}_{λ}^{0} ( λ ) T ( λ , d , {\hat{r}}_{23} ) {\vert {e}^{\frac{2 iπ}{λ} ( {n}_{2} ( λ ) + {iκ}_{2} ( λ ) ) x} - {\hat{r}}_{23} {e}^{\frac{2 iπ}{λ} ( {n}_{2} ( λ ) + {iκ}_{2} ( λ ) ) ( 2 d - x )} \vert}^{2} \\ where now & ( eqn . 4 ) \\ T ( λ , d , {\hat{r}}_{23} ) = \frac{{n}_{2} ( λ )}{{n}_{1} ( λ )} {\vert \frac{2 {n}_{1} ( λ )}{\begin{matrix}{n}_{1} ( λ ) + {n}_{2} + {iκ}_{2} ( λ ) + \\ {\hat{r}}_{23} [ {n}_{1} ( λ ) - {n}_{2} ( λ ) - {iκ}_{2} ( λ ) ] {e}^{\frac{4 iπ}{λ} ( {n}_{2} ( λ ) + {iκ}_{2} ( λ ) ) d}\end{matrix}} \vert}^{2} & ( eqn . 4 A )\end{matrix}$$

and \hat{r}₂₃=(\hat{n}₂−\hat{n}₃)⁻¹ is the reflection coefficient at the film/substrate interface (i.e. at x=d). The expressions for the extreme cases of perfect reflective or transparent substrates (eqn. 2 or 3, respectively) can be obtained from this general expression (eqn. 4) by substituting \hat{r}₂₃=1 or 0, respectively. \hat{n}=n+iκ is the complex refraction index of the material, with the subscript 1 for the surrounding (e.g., water), 2 for the photo-absorber thin film, (e.g. α-Fe₂O₃), and 3 for the back-reflector (e.g., silver, aluminum, gold, platinum or any other reflective material).

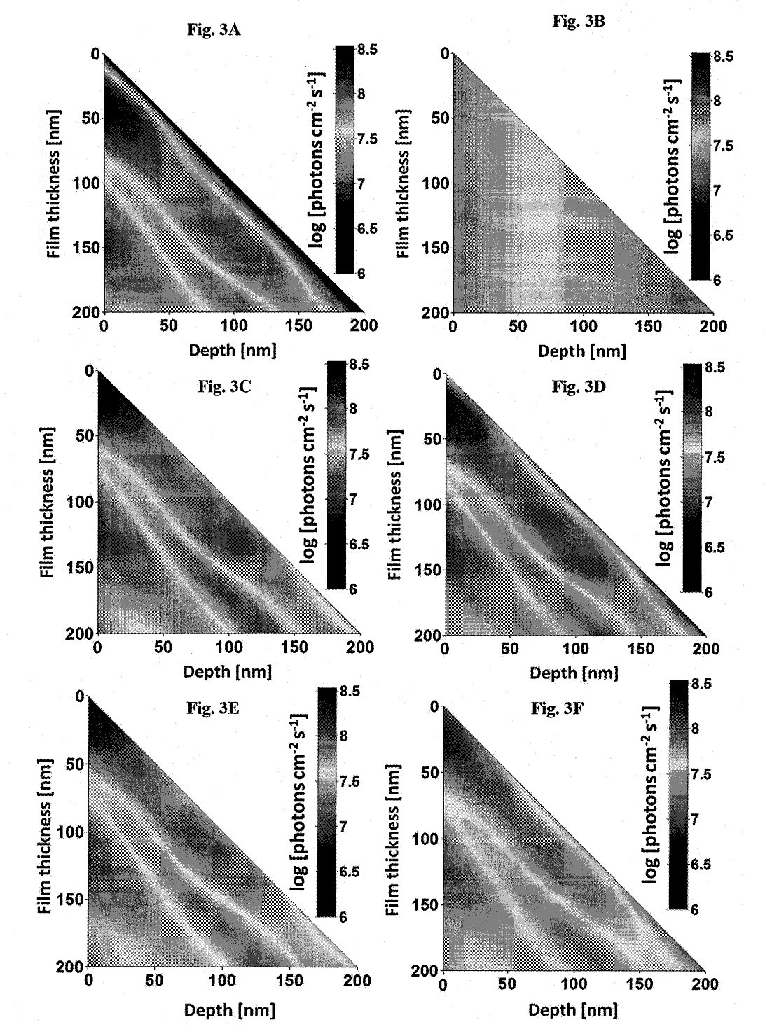

Reference is now made to FIGS. 3A-3F showing calculations of the photon flux profiles as a function of film thickness (d) and depth (x) from the surface into the photo absorber film. The results shown in these figures were calculated for the case of α-Fe₂O₃ films on perfect reflective (\hat{r}₂₃=1, FIG. 3A), transparent (\hat{r}₂₃=0, FIG. 3B), and various partially reflective substrates (0<\hat{r}₂₃<1, FIGS. 3C-3F) where the substrates are coated with silver (Ag, FIG. 3C), aluminum (Al, FIG. 3D), gold (Au, FIG. 3E) or platinum (Pt, FIG. 3F). These photon flux profiles were obtained by integrating the spectral photon flux profiles (calculated using equations 2, 3 or 4, respectively) between λₘᵢₙ=300 nm and λₘₐₓ=590 nm, i(x)=∫_{λ}_{ₘᵢₙ}^{λ}^{ₘₐₓ}I_{λ}(λ,x)dλ, being an example for usable solar radiation absorbed by α-Fe₂O₃. It should be noted that for other photo-absorber (semiconductor) materials this calculation would be modified in order to take into account the specific absorption spectrum of the material, and thus the parameters for absorption, refraction and λₘₐₓ would be altered according to the specific material. The incident spectral photon flux, I_{λ}⁰(λ) for this example is obtained from the solar irradiance spectrum, E_{λ}^{Sun}(λ), using the ASTM G173-03 standard and the relation

I_{λ}⁰(λ)=I_{λ}^{Sun}(λ)=λE_{λ}^{Sun}(λ)/hc

where h is Planck's constant and c is the speed of light in vacuum. The values for the refractive index n and the attenuation index κ of α-Fe₂O₃ and the different metal coatings (Ag, Al, Au and Pt) were measured by spectroscopic ellipsometry.

As seen from these figures, the photon flux profiles for films on reflective substrates display periodic dependence on the film thickness. The first resonance mode of the ideal cavity (FIG. 3A) is seen at a film thickness of 43 nm, where the maximal intensity is seen at the surface of the photo absorber 20. In the partially-reflective metal-coated substrates the photon flux is somewhat smaller and the resonance modes, providing high intensity, are shifted to smaller film thicknesses (thinner films). These effects result from the finite conductivity of the metal, giving rise to losses due to absorption in the metal coating and phase changes which are larger than π at the film/substrate interface (x=d). The inventors have found that these losses are relatively low for silver and aluminum reflective coatings (FIGS. 3C-3D), while being somewhat higher in the platinum and gold coatings (FIGS. 3E-3F). Additionally, for silver, gold, platinum or aluminum coatings, the first resonance mode is found to exist at film thicknesses of 20, 20, 24 or 30 nm respectively. Thus, as indicated above, the optical characteristics of the reflective coating are to be considered to determine the optimal film thickness.

The inventors have shown that the light intensity in ultrathin photo-absorber films located on at least partially reflective substrates can be markedly enhanced compared to identical films on transparent substrates, resonating at the surface of (approximately) quarter-wave films. Additionally, an optimal thickness of the photo-absorber film can be found, providing high photon flux and high photon density close to the surface of the film. Concentrating the light intensity close to the surface enables the photogenerated minority carriers (holes in the case of α-Fe₂O₃) to reach the surface and be injected to the electrolyte or collected by an electrode connected thereto. The injected charge carriers can thereby drive the water splitting reaction or any other chemical reaction in a photoelectrochemical cell, without being lost to bulk recombination. This is of the outmost importance for boosting the water photo-oxidation current density of α-Fe₂O₃ photoanodes.

In order to empirically verify the above calculations the inventors have deposited films of α-Fe₂O₃ having different thicknesses, dopes with Ti at 1%, on Pt-coated fused silica wafers in order to measure the total reflectance spectra, ρ(λ,d), and obtain the absorptance spectra α(λ,d)=1−ρ(λ,d) of the films. The latter is used to calculate the absorbed photon flux in the specimen (comprising both film and substrate) under standard solar irradiance conditions using the formula

$${I}_{abs} ( d ) = {\int }_{{λ}_{min}}^{{λ}_{max}} {I}_{λ}^{Sun} ( λ ) a ( λ , d ) d λ . \qquad ( eqn . 5 )$$

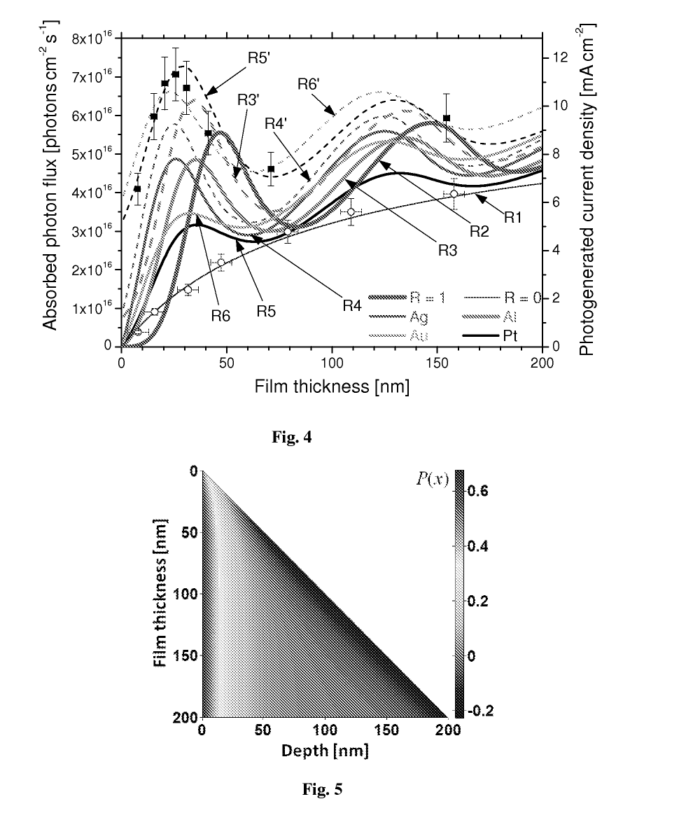

The experimental results are shown in FIG. 4 together with the theoretical calculations described above. FIG. 4 illustrates the absorbed photon flux on the left vertical axis and the photogenerated current density, J_{pg}=qI_{abs}, on the right vertical axis with respect to the film thickness d (horizontal axis). In the figure, graphs R1 to R6 correspond to the (calculated) absorption for the structures utilizing respectively transparent, fully reflective, Al, Ag, Pt, and Au back reflectors. The solid curves correspond to the (calculated) absorption in the photo-active films, and the dashed curves R3′ to R6′ correspond to (calculated) absorption in the entire structure including absorption in the photo-active film and in the substrate. Symbols show measured results. As seen from this figure, the experimental results (shown as squares) provide good fit with the theoretical, calculated curve (dashed curve R5′) that takes into account the absorption in the α-Fe₂O₃ films as well as in the Pt-coated substrates. It should be noted that platinum absorbs light in a spectral range overlapping with the absorption of α-Fe₂O₃, therefore a considerable fraction of the measured absorption occurred in the platinum coating rather than in the α-Fe₂O₃ film. This results in substantial optical loss which can be mitigated by replacing platinum with highly reflective metals such as aluminum or silver.

The net absorption in the α-Fe₂O₃ films on Pt-coated partially reflective substrate, calculated by integrating the respective photon flux profiles shown in FIG. 3F across the entire film thickness, is depicted by curve R5 in FIG. 4. As can be seen, a local maximum of absorption exists at d=36±1 nm. At this thickness the absorbed photons generate current density of J_{pg}=5.1 mA cm⁻², which corresponds to 40% of the ultimate limit (12.6 mA cm⁻²) set by the energy band gap of α-Fe₂O₃. It should be noted that a perfect reflective substrate (R=1) can provide that the absorptance in a 47 nm thick α-Fe₂O₃ films would reach 71% of the theoretical limit These results demonstrate the effectiveness of the light trapping scheme according to the present invention, since the same photo-absorber film placed on a transparent substrates (R=0) can absorb only 27% of the theoretical limit Thus, the optical efficiency of ca. 40 to 50 nm thick α-Fe₂O₃ photoanodes can be almost tripled by replacing the ubiquitous transparent substrates with highly reflecting ones. It should be understood that thicker films will absorb more of the incident light but the charge carriers may be generated further into the film and thus may not reach the surface to induce the desired reaction (e.g. water photo-oxidation). The minority carriers generated deeper than ca. 25 nm from the surface tend to recombine with majority carriers before reaching the electrode/electrolyte interfaces. Similar calculations for α-Fe₂O₃ films on silver, aluminum and gold coated substrates display high optical gains (see inset of FIG. 4), reaching a maximum gain of 4.2 for a 16 nm thick film on a silver coated substrate.

Thus, the light trapping in ultrathin absorbing films approach of the present invention, utilizing interference effects enabled by the use of back reflectors (e.g., metallic reflective layers), enhances light absorption in photo-absorbers for photoelectric and photoelectrochemical applications. It should be noted that the light trapping scheme of the present invention is different from the standard route of light trapping in thin film solar cells wherein textured substrates are used as Lambertian reflectors to randomize the direction of the light reaching the bottom of the film in order to allow much of it to be totally internally reflected and remain trapped in the film. This is while the standard approach works for films of thickness much larger than half wavelength (d>>λ/2n), the technique of the present invention is ideally suited for quarter-wave films (d=λ/4n). Therefore, it works well for ultrathin films far below the minimum thickness required for the standard light trapping approach. As indicated above, the present invention utilize concentration of light intensity close to the surface of thin (quarter-wave-like) films, as demonstrated in FIG. 3A and FIGS. 3C-F, which boosts the generation, separation and collection of charge carriers to provide higher photocurrent density generated by ultrathin photo-absorbers (e.g. α-Fe₂O₃).

As indicated above the current density, Jₚₕₒₜₒ, generated by the absorbed photons can be written as the product of the number of minority carrier generated per unit time and unit volume at distance x from the surface g(x), and the probability P(x) for those carriers to reach the surface and be injected to the electrolyte or collected by electric contacts, integrated over the entire thickness of the film and multiplied by the elementary charge unit q:

$${J}_{photo} ( d ) = q {\int }_{0}^{d} g ( x ) P ( x ) d x . \qquad ( eqn . 6 )$$

The minority carrier generation term, g(x), is the product of the spectral photon flux profile inside the film, I_{λ}(x,λ), and the absorption coefficient, α(x), integrated over the absorbed wavelength range:

$$g ( x ) = {\int }_{{λ}_{min}}^{{λ}_{max}} {I}_{λ} ( λ , x ) α ( λ ) d λ . \qquad ( eqn . 7 )$$

P(x) is the probability for the photogenerated minority charge carriers to separate from the majority carriers, reach the surface and drive desired reaction. In connection to water photo-oxidization or other solution based chemical reactions, only those charge carriers reaching the front surface of the film and are forward injected to the electrolyte contribute to the water splitting process, while those reaching the back interface and being backward injected to the substrate reduce the photocurrent. This can be estimated by designating the probability for charge separation and transport in the forward direction, i.e. minority charge carriers going towards the surface. It should be noted that Φ is typically determined by the symmetry of the electrochemical potential gradient across the film. The collection probability of minority charge carriers generated at a distance x from the surface scales exponentially with −x/L, where L is their collection length. Designating \vec{P}_{F} the probability for forward injection to the electrolyte by i.e., the probability for minority charge carriers that have reached the surface to drive the desired electrochemical reaction by reacting with the respective surface adsorbates, the fraction of photogenerated minority charge carriers that end up with a positive contribution to the photocurrent is \vec{P}_{F}Φe^{-x/L}. Likewise, the fraction of their counterparts ending up with a negative contribution due to backward injection to the substrate is [symbol] _{B}(1−Φ)e^{-(d-x)/L}, where [symbol] _{B} is the probability for backward injection. All in all, the minority carriers separation and collection probability distribution function is:

P(x)=\vec{P}_{F}Φe^{-x/L}− [symbol] _{B}(1−Φ)e^{-(d-x)/L}. (eqn. 8)

Reference is made to FIG. 5 showing the minority carrier separation and collection probability P(x) as a function of the layer thickness d and for different depths x within the layer for Φ=0.75, \vec{P}_{F}= [symbol] _{B}=0.9, and L=20 nm. These values were found to fit well the photocurrent densities obtained experimentally with α-Fe₂O₃ films on platinized reflective substrates, and they are within range of the expected values. The collection probability P(x) is relatively high (>60%) close to the surface, however it decays exponentially to near zero values deeper than ˜20 nm from the surface, reaching negative values close to the interface with the substrate. It should be noted that negative values of the collection probability P(x) actually mean that more charge carriers are injected backward towards the reflective surface. Such back injected carriers may be used for photoelectric cells but are typically useless for solution base photo-electrochemical cell units.

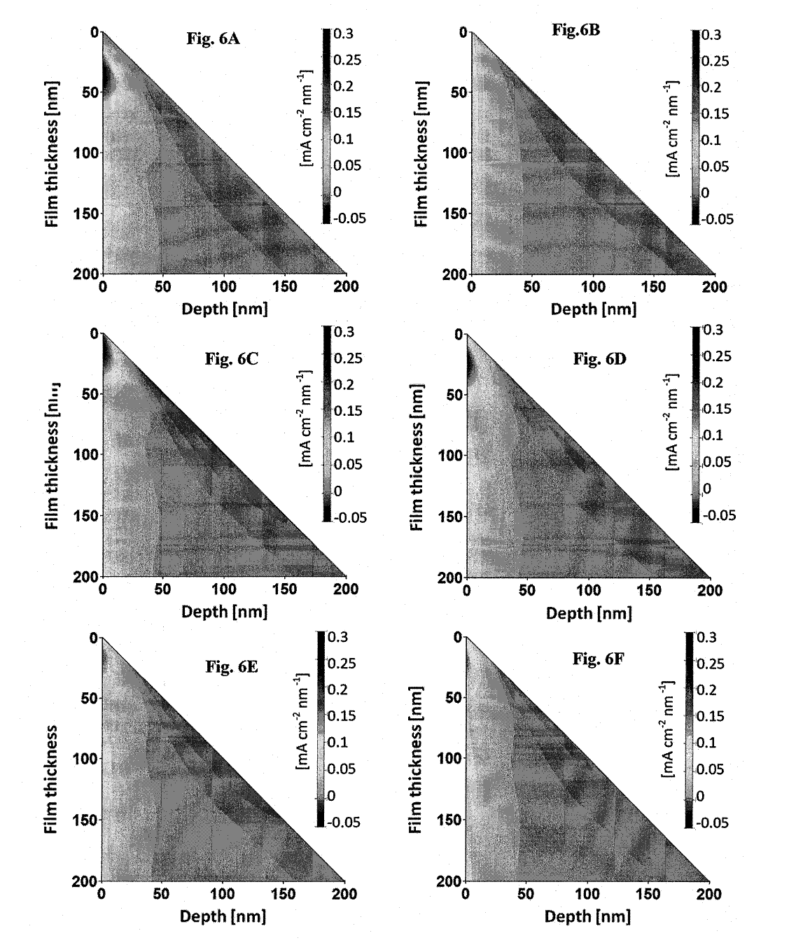

Reference is made to FIGS. 6A-6F showing the photocurrent density per unit volume profiles, dJₚₕₒₜₒ/dx=qg(x)P(x), for α-Fe₂O₃ films on perfect reflective (FIG. 6A), perfectly transparent (FIG. 6B), and partially reflective substrates coated with silver (FIG. 6C), aluminum (FIG. 6D), gold (FIG. 6E) or platinum (FIG. 6F). The minority carrier generation profiles, g(x), are calculated using the respective photon flux profiles in FIG. 3, and P(x) is taken from the calculation shown in FIG. 5. These profiles reveal the importance of concentrating the light intensity close to the surface of the photoanode. This is since light components being absorbed further than ca. twice the minority carrier collection length from the surface add very little to the water photo-oxidation current density (or any other reaction process), because the minority carriers recombine with majority carriers before reaching the surface.

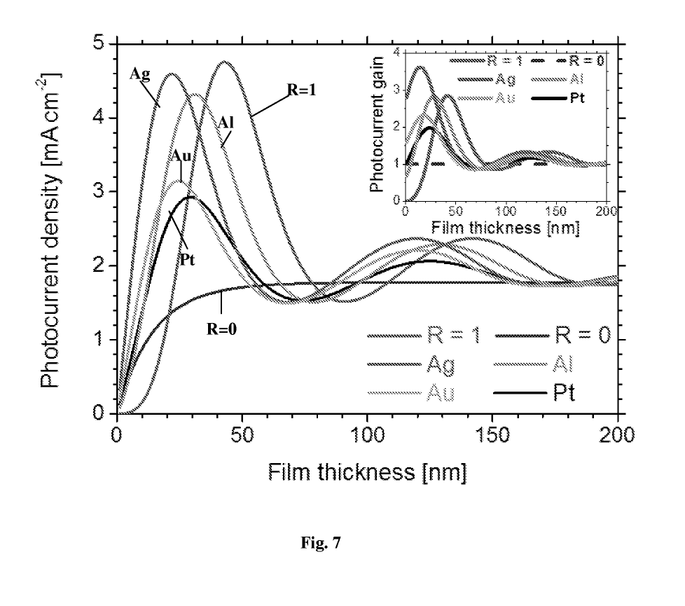

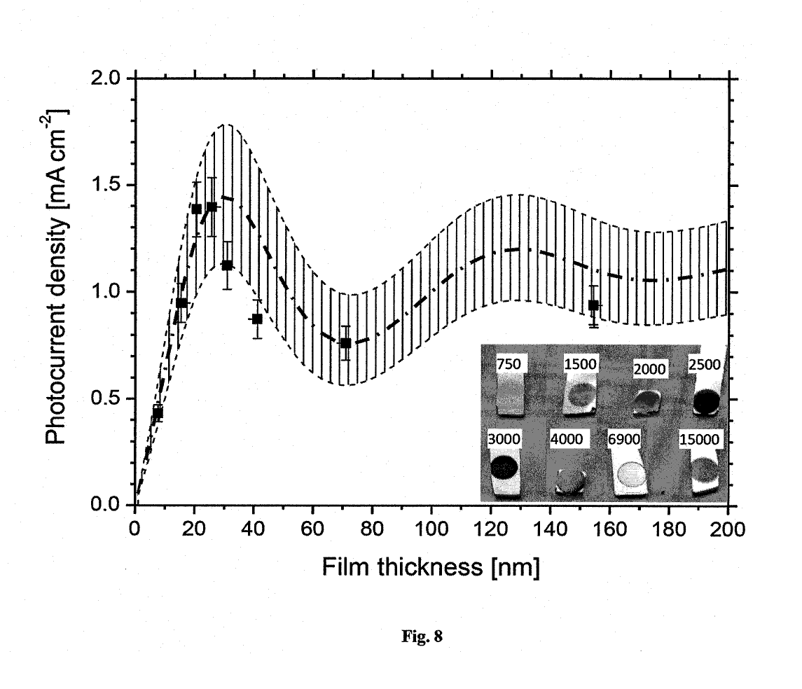

The photocurrent density per unit area, Jₚₕₒₜₒ, is obtained by integrating the photocurrent density per unit volume profiles over the entire film thickness. FIG. 7 shows the photocurrent density calculated as a function of film thickness for α-Fe₂O₃ films on different substrates, assuming ideal forward injection conditions (i.e., Φ=1 and \vec{P}_{F}=1). Such conditions may be realized using sufficiently high potentials (that can be reduced using catalysts) and selective transport layers to block the backward injection to the substrate (setting [symbol] _{B} to zero). Films on reflective substrates display periodic dependence of Jₚₕₒₜₒ on the film thickness. The first and foremost prominent peak in each of the graphs corresponds to the first resonance mode of the respective optical cavities. These peaks are quite narrow and therefore the film thickness must be precisely tuned to achieve the optimal performance, an offset of just a few nm significantly decreases the photocurrent. The graphs illustrated in FIG. 7 show that a maximum current density of 4.8 mA cm⁻² is expected for a 43 nm thick film on an ideally reflective substrate (R=1). This value exceeds the world record obtained with the champion α-Fe₂O₃ photoanode reported to date by more than 50%, demonstrating the potential advantage of the technique of the present invention utilizing ultrathin film optical cavities. Photo-absorbing thin film having thickness of 22, 31, 24 and 29 nm and utilizing silver (Ag), aluminum (Al), gold (Au) and platinum (Pt) coated substrates, respectively, are expected to generate photocurrent densities of 4.6, 4.3, 3.1 and 2.9 mA cm⁻². The photocurrent gain with respect to films (of the same thickness) on transparent substrates is shown in the inset of FIG. 7. This figured demonstrate that optical cavities comprising ultrathin α-Fe₂O₃ films display considerable gains reaching 3.6, 2.8, 2.3 and 2.0 for 14, 28, 18 and 24 nm thick films on silver, aluminum, gold or platinum coated substrates, respectively, while the gain for films on ideally reflective substrates reaches 2.9 for a 42 nm thick film.

In order to verify this model calculations the photocurrent density of Ti-doped α-Fe₂O₃ films on platinized fused silica substrates was measured in 1 M NaOH solution under 100 mW cm⁻² white light illumination. FIG. 8 shows the photocurrent density measured at an applied potential of 1.4 V_{RHE}. It should be noted that higher currents can be obtained at higher (more positive) potentials. The experimental results were fitted with model calculations using L and Φ as fitting parameters. \vec{P}_{F}=0.9 was taken based on injection efficiency measurements, and [symbol] _{B} was assumed to be equal to \vec{P}_{F}. All the other parameters were obtained from optical measurements of the specimens, or from the literature in the case of the optical constants of platinum. As can be seen from the figure, the case of L=20±3 nm and Φ=0.75±0.05 provided excellent agreement with the theory, validating the model calculations. The collection length L result from the fitting is within range of the reported values for donor-doped α-Fe₂O₃ photoanodes. The periodic dependence on the film thickness is a clear evidence of the interference effects discussed before.

The photocurrent density reaches a maximum of 1.4±0.2 mA cm⁻² for the 26±3 nm thick film, surpassing the maximum photocurrent density obtained with any of the films on transparent substrates by 40%. Compared to previous reports on ultrathin α-Fe₂O₃ photoanodes^{Error! Bookmark not defined}. The configuration of the present invention can achieve more than a twofold enhancement in the photocurrent density, with the previous record standing at 0.63 mA cm⁻² at 1.5 V_{RHE}.^{Error! Bookmark not defined}. This result demonstrates the effectiveness of the light trapping scheme for boosting the water photo-oxidation efficiency of ultrathin α-Fe₂O₃ photoanodes.

The highest photocurrent density obtained in this measurement is 1.4±0.2 mAcm⁻² for the 26±3 nm thick film, reaches about 50% of the expected theoretical maximum calculated for the same design with the same film thickness assuming ideal forward injection condition (2.9 mA cm⁻² for a film thickness of 29 nm, as shown in FIG. 7). The highest photocurrent is observed experimentally at the predicted film thickness, but it reaches only a half of the predicted value. This highlights the importance of blocking the backward injection of minority charge carriers to the substrate, which is particularly critical in ultrathin films wherein a sizeable portion of the photogeneration occurs close to the back interface with the substrate.

Further improvements in the solar to hydrogen conversion efficiency of ultrathin film α-Fe₂O₃ photoanodes can be achieved by improving the substrate reflectivity, blocking the backward hole injection to the substrate, and enhancing the forward injection to the electrolyte. The latter can be achieved using water oxidation catalysts such as Co, IrO₂, or cobalt phosphate (Co—Pi). The substrate reflectivity can be markedly enhanced by replacing the platinum coating with highly reflective metal coatings such as silver or aluminum (as shown in FIG. 3D and FIG. 5). Due to the reactivity of these metals with oxygen and water the substrates would have to be specially designed to prevent corrosion and collect the majority carriers from the photoanode. One possibility is inserting a transparent conducting oxide layer such as FTO between the metalized substrate and the photoanode. This would also reduce the backward injection of holes to the substrate. However, these multilayer stacks would have to be designed to optimize their light harvesting and charge collection efficiencies using similar principles and methodology as described in the present invention. A generalized approach for optimizing such multilayer stacks is presented further below.

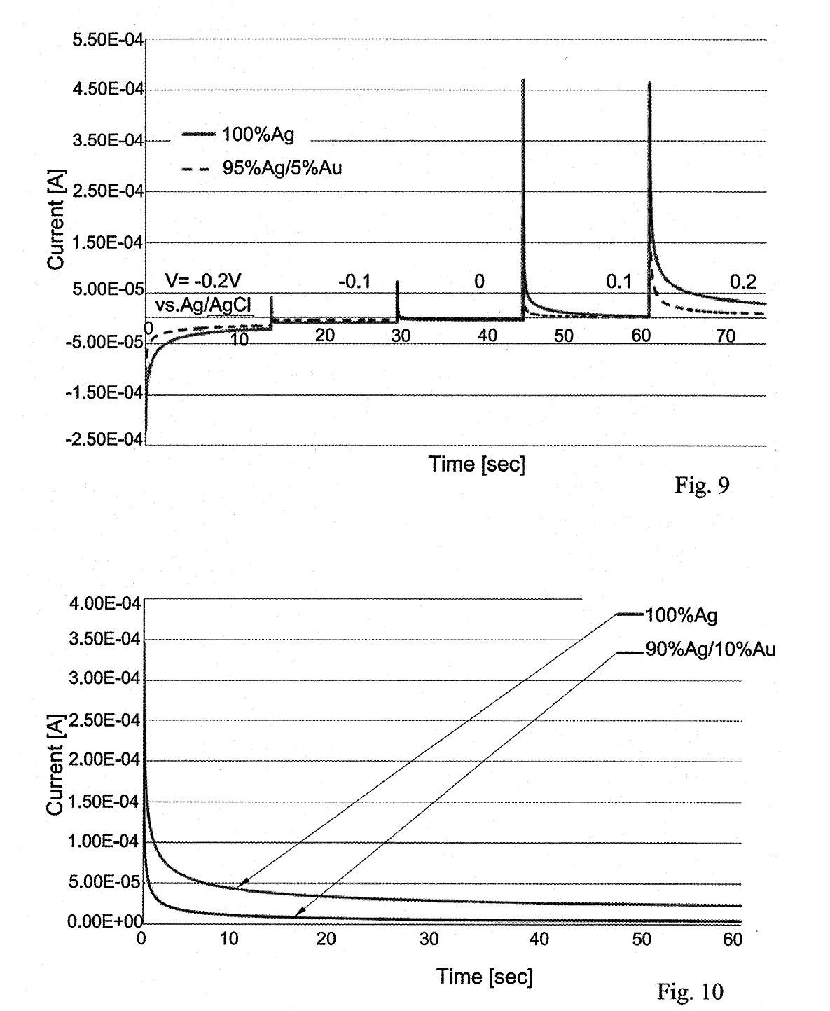

In order to further improve the conversion efficiency of these photoelectrodes, the inventors explored different metallic back reflectors, including aluminum (Al), silver (Ag), silver-platinum (Ag—Pt) and silver-gold (Ag—Au) alloys. Al and Ag coated substrates were found to improve the light absorption efficiency in the α-Fe₂O₃ films compared to Pt coated substrates, but these specimens are unstable in aqueous solutions giving rise to decomposition (Ag) and corrosion (Al) during the electrochemical and photoelectrochemical tests. To rectify this deficiency the inventors explored Ag—Pt and Ag—Au alloys with 10% to 22% Pt or 5% to 15% Au, respectively. Both alloys were found to be significantly more stable that pristine Ag in electrochemical tests in aqueous solutions. This is demonstrated in FIG. 9 showing measurement of current through silver (100% Ag) and silver-gold (95% Ag-5% Au) coated fused silica substrates in 1M NaOH solution (pH of ˜14) with different potentials ranging between −0.2 and +0.2 volts, against the Ag/AgCl reference electrode applied to the working electrode. The silver coated substrate displays significant current densities at +0.2 V vs. Ag/AgCl with obvious visual signs of corrosion, while the silver-gold alloy (95% Ag-5% Au) coated specimen remains stable with negligible current measured at the same potential. The results of a similar test carried out with another silver-gold alloy (90% Ag-10% Au) at a potential of +0.2 V vs. Ag/AgCl shows negligible current following the initial spike upon switching the potential to +0.2 V vs. Ag/AgCl, as demonstrated in FIG. 10. The spikes in both FIG. 9 and FIG. 10, emerge from the transient response of the system upon changing the potential applied to the electrode. However these spikes are not indicative of degradation processes. It should be noted that the steady state current is indicative of degradation of the electrode, and the lower the steady state current indicates higher stability of the electrode.

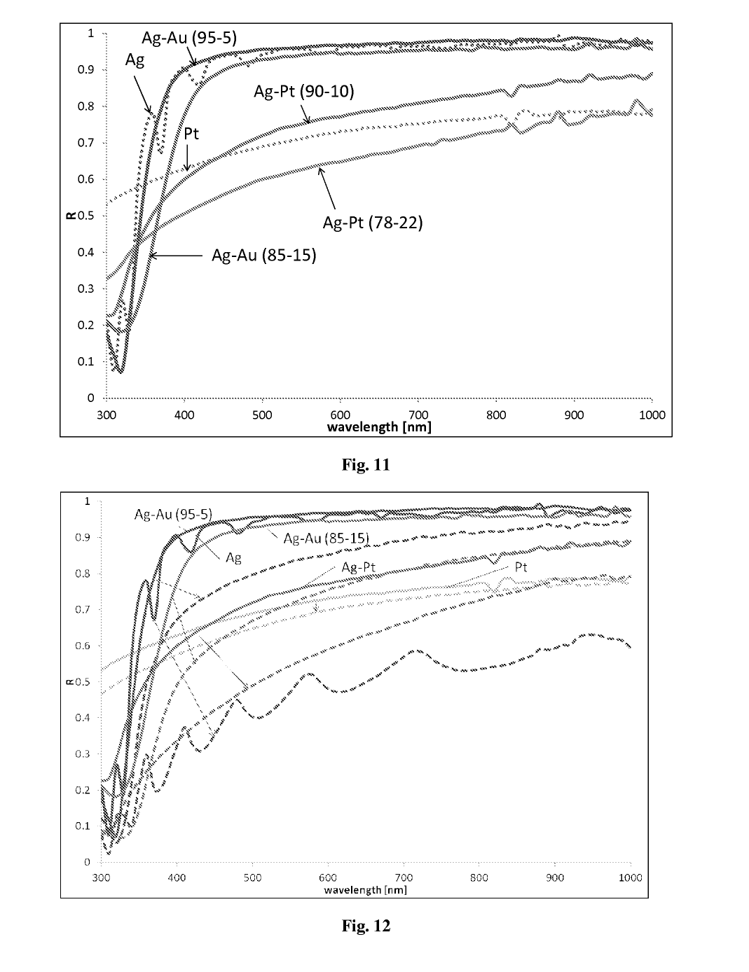

The optical properties of the silver-gold alloys are nearly the same as pristine silver, as demonstrated in FIG. 11 showing the reflectance (R) as a function of wavelength for Pt, Ag, Ag—Pt alloys (with 10% or 22% Pt) and Ag—Au alloys (with 5% or 15% Au). The reflectivity measurements in FIG. 11 were carried out following the metal coating deposition, with no heating applied to the specimens. Upon heating, especially in oxygen containing atmospheres, silver is known to lose its transparency due to surface roughening and oxidation. The inventors have found that the silver-gold alloys maintain high reflectivity, considerably higher than pristine silver, following heating to 450° C. in oxygen, as demonstrated in FIG. 12 showing the different reflectance before and after heating of the samples. This characteristic may be important since α-Fe₂O₃ films, as well as other metal-oxide semiconductor photo-absorbers, are typically deposited on the metal coated substrate at high temperatures (typically above 400° C.) in oxygen or oxygen containing atmosphere. Thus, inventors have found that silver-gold alloys with 5% to 15% Au are highly suitable to serve as back reflectors in aqueous environments and specifically for the purposes of the present application.

The inventors examined different structures employing silver-gold alloy back reflectors and α-Fe₂O₃ thin film photoanodes and have found that in order to achieve stable and efficient operation as photoanodes for water photo-oxidation a thin hole blocking layer should preferably be placed between the α-Fe₂O₃ photoanode and the silver-gold alloy coated substrate. Additionally a diffusion barrier layers should be placed directly below and above the silver-gold alloy layer to prevent silver diffusion out of this layer into the substrate and into the oxide layers on top of the back reflectors. The inventors found that SnO₂ may serve as a good hole blocking layer, configured as a 10-30 nm thin SnO₂ film located below the α-Fe₂O₃ thin film photoanode (being 10-30 nm thick). This SnO₂ film improves stability and photo-conversion efficiency. As for the diffusion barriers, the inventors have found that thin (10-50 nm) TiN films placed below and above the silver-gold alloy layer stabilize this layer against inter-diffusion and reaction with the other components of the device. To this end FIG. 13 illustrates a photoanode structure 10 including a photo-absorber 20 located on a metallic reflective surface 30 deposited on a substrate 40, a spacer between them which includes a hole-blocking layer 25 (constituting the charge carriers collection structure) and also includes in this specific not limiting example a diffusion barrier layer 28, and an optional additional diffusion barrier layer 28 located between the reflective layer 30 and the substrate 40. The photoelectrochemical performance of the device 10 were measured in 1 M NaOH solution in the dark and under cyclic exposure to 100 mW cm⁻² white light illumination at electrode potentials of 1.03 to 1.63 volts vs. the reversible hydrogen electrode (RHE) scale, the results are shown in FIG. 14. The device 10 provided photocurrent densities as high as 2 mA cm⁻² showing no signs of degradation. The following are some examples of systems utilizing the above described photoelectrode (or photoelectrochemical cell) of the present invention.

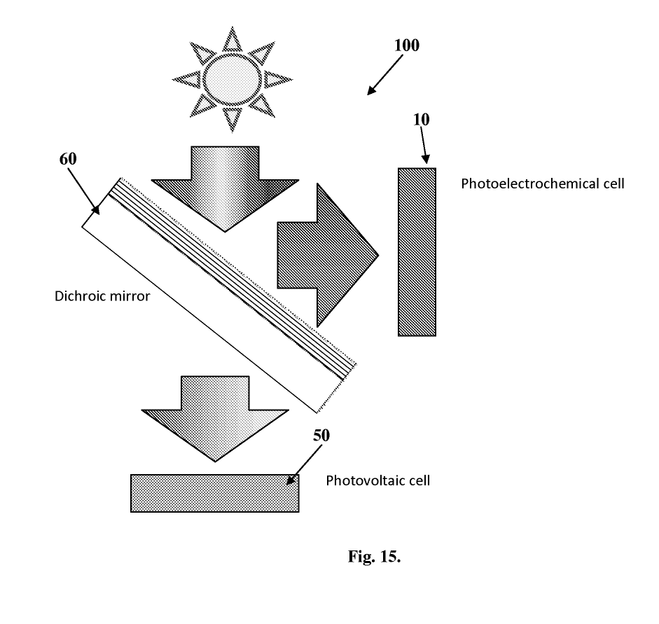

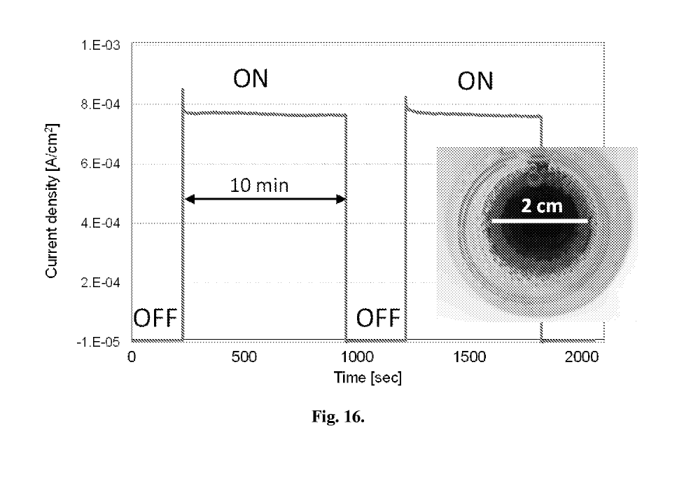

Reference is made to FIGS. 15 and 16 illustrating a hybrid system 100 of the invention formed by photoelectrochemical and photovoltaic cells and efficiency measurement result of such hybrid system. FIG. 15 schematically illustrates the hybrid energy conversion system 100 including a photoelectrochemical cell 10 in tandem with a photovoltaic cell 50 where a dichroic, or wavelength selective mirror (beam splitter) 60 is configured to split the incident light to two spectral ranges and direct the appropriate light components either to the PV cell 50 or the photoelectrochemical cell 10 configured as described above. The wavelength selective reflector (e.g. dichroic mirror) acts as a beam splitter that splits incident electromagnetic radiation (sunlight) into two spectral ranges, one being directed to the photoelectrochemical cell and the other to the photovoltaic cell. Preferably the spectral splitting is selected to maximize operation of the different cells.

The results shown in FIG. 16 correspond to the tandem cell system 100 of FIG. 15, showing the water photo-oxidation current density obtained using a photoanode made of a thin (˜30-40 nm) α-Fe₂O₃ film on Pt-coated silica wafer and arranged in tandem cell configuration with a Si photovoltaic cell with a dichroic mirror serving as a beam splitter. The measurement was carried out in 1 M NaOH aqueous solution for the photoelectrochemical unit 10, during light on/off cyclic exposure to simulated solar radiation (equivalent to 1 Sun at AM1.5G conditions), and the photoanode was connected to a commercially available Si-based photovoltaic cell rated to generate 11 mA at 1.53 Volt at its maximum power operation point.

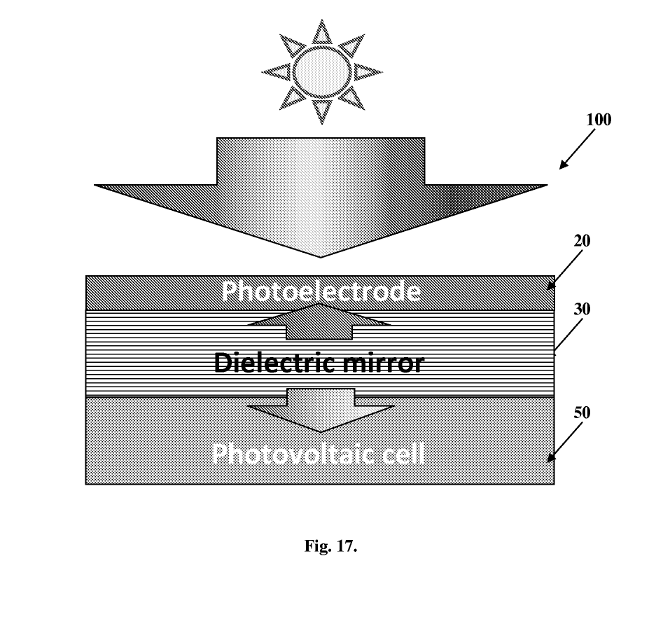

FIG. 17 illustrates an example of a hybrid cell system 100, configured as a monolithic system. The system 100 includes another configuration of radiation conversion device of the invention, in which the photo-absorber unit directly interfaces with the at least partially reflective structure, similar to the example of FIG. 2. More specifically, the photoelectrode 20 in tandem with a photovoltaic cell 50 configured such that an interconnecting layer between the photoelectrode 20 and the photovoltaic cell 50 acts as a wavelength selective reflector (e.g., dielectric mirrors or distributed Bragg reflectors) which constitutes the at least partially reflective structure 30. The partially reflective interconnect 30 serves as a beam splitter or spectral selective filter for splitting the incident radiation into two spectral ranges, one being reflected back to the photoelectrode 20 and the other passing through to the photovoltaic cell 50.

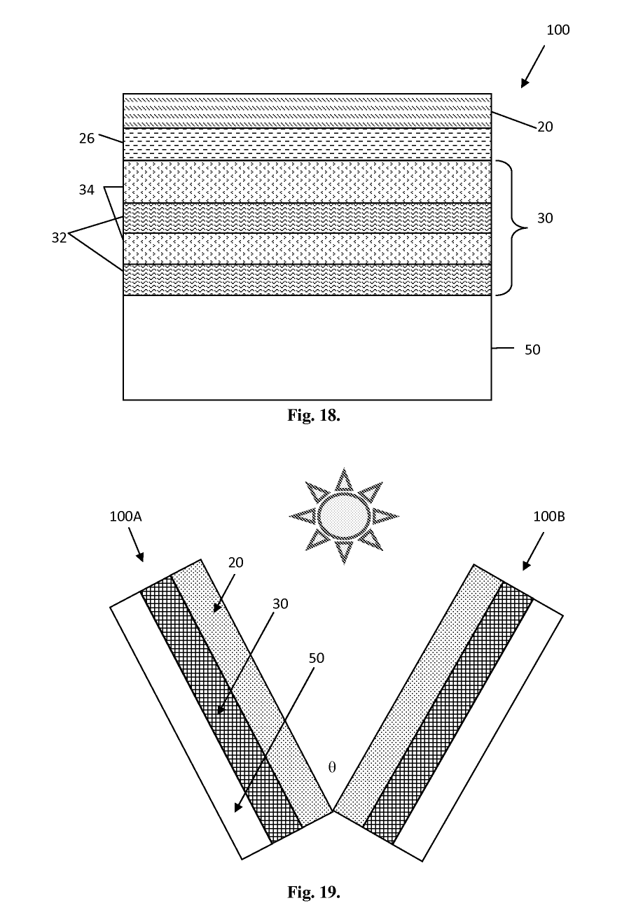

FIG. 18 shows a specific but not limiting example of a monolithic device 100 configuration, in which similar to that shown in FIG. 17, the at least partially reflective structure is a multi-layer structure (i.e. defining multiple reflective interfaces) and similar to the example of FIG. 13, a spacer between the photo-absorber unit and the at least partially reflective structure includes a transparent electrode. Thus, in this example, the monolithic device includes a photo-absorbing semiconductor 20 (e.g. α-Fe₂O₃ layer) located on a transparent electrode layer 26 (e.g. F:SnO₂ or FTO layer) for charge collection and a back reflecting layer structure 30 configured as a dielectric mirror. The reflective layer 30 may be composed of alternating layers of SiO₂ and Nb₂O₅, for example a multilayer stack of 40 nm thick Nb₂O₅ layer on a 85 nm thick SiO₂ layer on a 45 nm Nb₂O₅ layer on a 115 nm thick SiO₂ layer, repeating 5 times and on top of it a 75 nm thick FTO (transparent electrode) and on top of it a 20 nm thick Ti-doped α-Fe₂O₃ film, and the structure immersed in water, would give rise to 33.6% of the solar photons (at AM1.5G one sun illumination conditions) of wavelengths below 590 nm absorbed in the α-Fe₂O₃ photoelectrode, 54% reflected back to water, 7% lost for absorption in the dielectric mirror stack, and the rest (5.4%) transmitted through the structure down to the PV cell below it. With reasonable assumptions on the carrier collection efficiency this would give rise to a photocurrent density of 2.12 mA cm⁻² for direct illumination (normal incident light) on a single unit, and up to 4.49 mA cm⁻² for two such units at an angle of 30° to each other—as shown in FIG. 19.

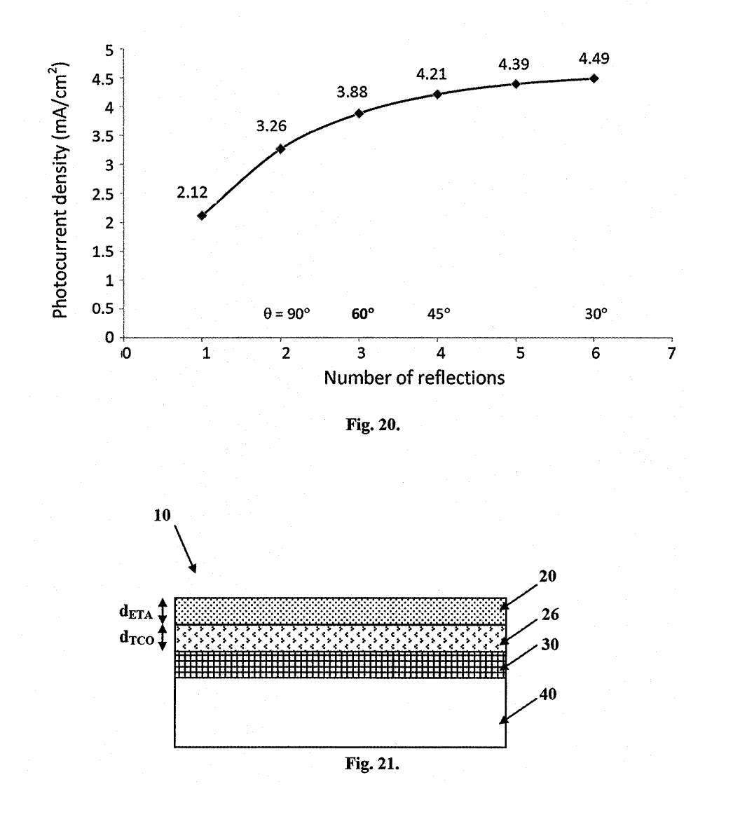

FIGS. 19 and 20 illustrate a V-shape structure comprising two monolithic cells 100A and 100B and corresponding photocurrent measurements respectively. The monolithic cell systems 100A and 100B are configured in a similar fashion to the example of FIG. 18. Here, the cell is immersed in a solution. The cell may include a counter electrode collecting the current on one end, and the back-reflector collecting the current on the other end. Alternatively, a transparent conducting electrode may be placed on top of the photoelectrode to collect the current from this side. This V-shape configuration enables to harvest some of the back-reflected light that leaves the photoelectrode and utilize such back-reflected light components by one other cell unit located in optical path of the back-reflected light components. The photocurrent density increases with the number of reflections between the two units, which is in turn determined by the angle between the units as will be described below.

FIG. 21 schematically illustrates a photoelectrochemical 10 design, configured for light trapping in ultrathin films, of a thickness below the λ/4n limit. In this example, the device is configured generally similar to FIGS. 13 and 18 in that the spacer between the photo-absorber unit and the at least partially reflective structure is provided including the transparent electrode for charge carriers' collection. As shown, the device includes a photoelectrode (photo-absorber unit), a transparent electrode (e.g. bilayer structure), and a reflective or partially reflective structure. The photoelectrode and the transparent electrode present together an antireflection coating on top of the reflective or partially reflective substrate. The trapped light in this bilayer structure is absorbed in the photoelectrode (top layer). This configuration utilizes a transparent conductive electrode 26 (e.g. F:SnO₂ or FTO layer) located between the at least partially reflective structure 30 and the light absorbing layer 20. The additional transparent conductive layer 26 may be used as a collector for majority charge carriers while blocking minority charge carriers to reduce the deleterious effect of back injected minority charge carriers. It may also be used as a diffusion barrier configured to prevent diffusion of material between the different layers. The structure, i.e. the light absorbing layer 20 and the transparent electrode layer 26, is configured as an antireflection coating on top of a reflective or partially reflective substrate as describe above. This design enables the photo absorber layer 20 to go beyond the λ/4n limit by splitting the total thickness (e.g., 20-40 nm in the case of α-Fe₂O₃ photoelectrodes) into two layers, one absorbing 20 (the photoelectrode—top layer) but the other transparent 26. Hence, now the light is confined in the bi-layer but it can only be absorbed in the photoelectrode. With this configuration, sub 10 nm photo-absorber films can be effectively used. Such ultrathin films typically display high charge separation and collection yields relative to their thicker counterparts, especially for poor transport semiconductor materials such as α-Fe₂O₃ with short (≦20 nm) diffusion length for minority charge carriers. As indicated above, a substrate of a photoelectrochemical cell may be replaced by a photovoltaic cell. In this case, the at least partially reflective structure includes a wavelength selective reflector. The thickness selection of the photo-absorbing layer 20 and the transparent layer 26 in this configuration, as well as in any other configuration utilizing plurality of transparent layers, can be determined by the generalized calculation approach described further below.

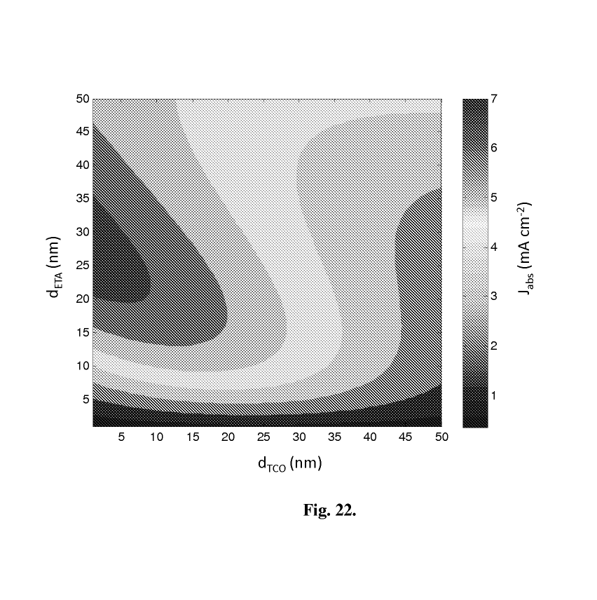

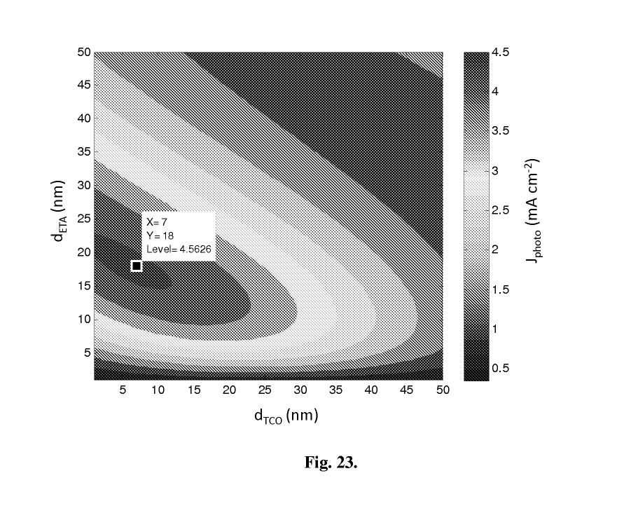

FIGS. 22 and 23 show calculated absorbed photon (J_{abs}) and photocurrent (Jₚₕₒₜₒ) densities, respectively, for photoelectrochemical cells structured as in FIG. 21 with Ag-coated substrate (silver back reflector) and SnO₂ transparent electrode (TCO), as a function of the thickness of the light absorbing layer 20 (d_ETA) and the thickness of the transparent electrode 26 (T_TCO). The maximum photocurrent density of 4.56 mA cm⁻² is obtained for 7 nm thick SnO₂ and 8 nm thick α-Fe₂O₃.

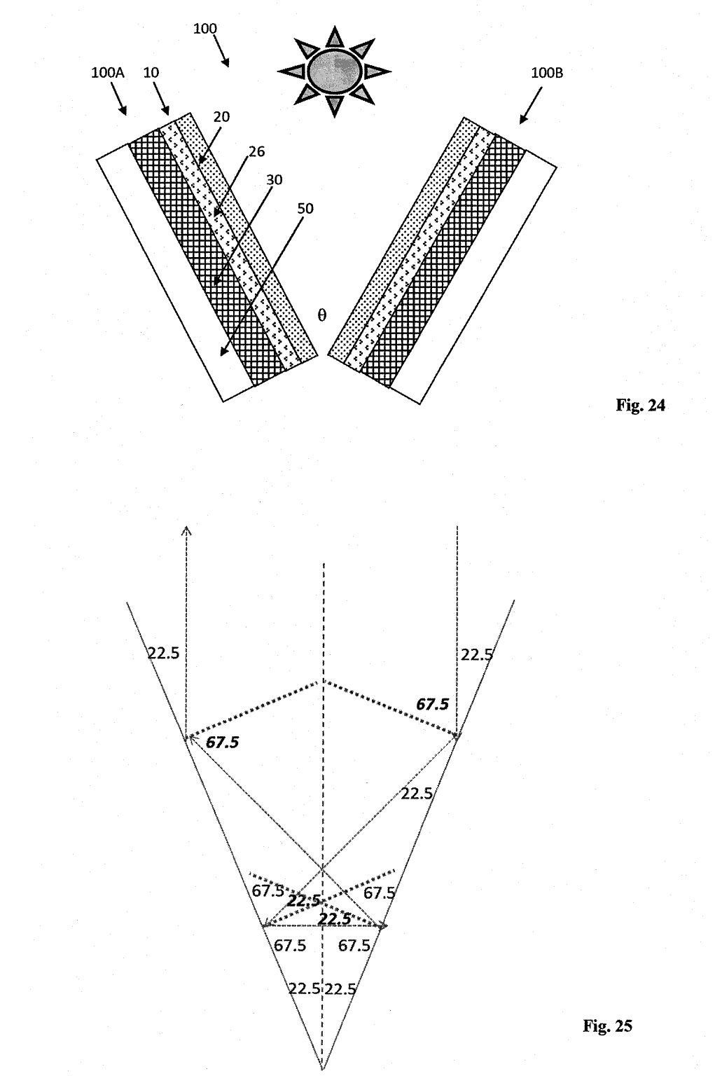

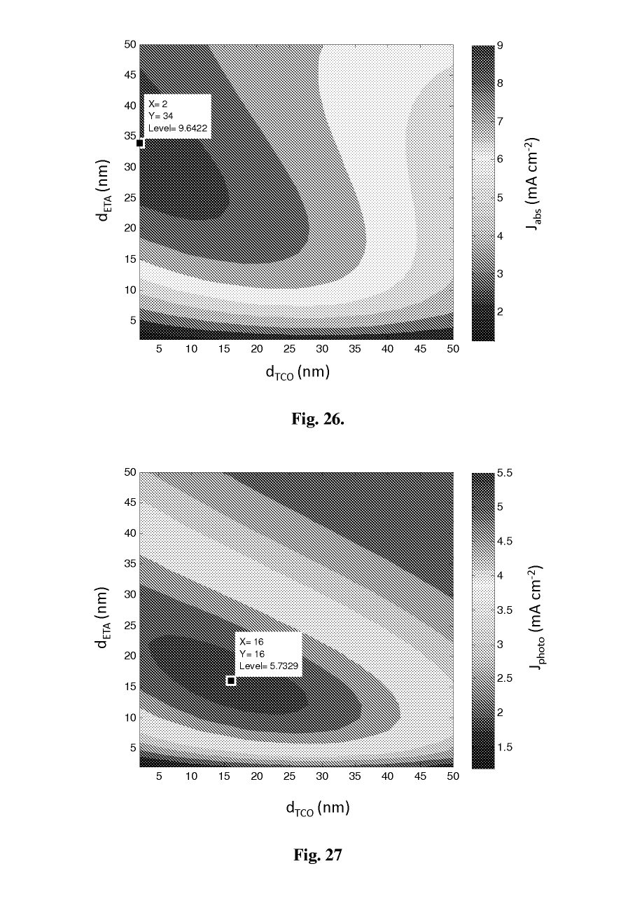

FIG. 24 is a schematic illustration of a general V-shape structure 100 formed by two photoelectrodes 10 displaying light trapping in sub λ/4n films as described above (with reference to FIG. 21 and to FIG. 19). FIG. 25 schematically illustrates light beam passing and being reflected within a V-shape structure configured with 30 degrees between the two units providing at least four reflections between the units. It should be noted that only a part of the incident light is reflected back from the unit, however by utilizing this portion of the light the efficiency of the system may increase. The photoelectrode units may utilize silver (Ag) or silver-gold alloy (with 5% to 15% gold) coated reflective substrates, 28 nm thick TiO₂ and SnO₂ transparent electrodes, and ultrathin α-Fe₂O₃ photoelectrodes. FIGS. 26 to 31 show the expected performance of such V-shape cell structure (in terms of water photo-oxidation current density) as a function of the angle θ between the two units.

FIGS. 26 and 27 show calculated optical performance, in terms of the calculated absorbed current density and water photo-oxidation current density respectively, for the V shape cell as illustrated in FIG. 24 with an angle (θ) of 90° between the two photoelectrodes, Ag reflective coating (back reflector), α-Fe₂O₃ photo-absorber layer (ETA) and SnO₂ transparent electrode layer (TCO).

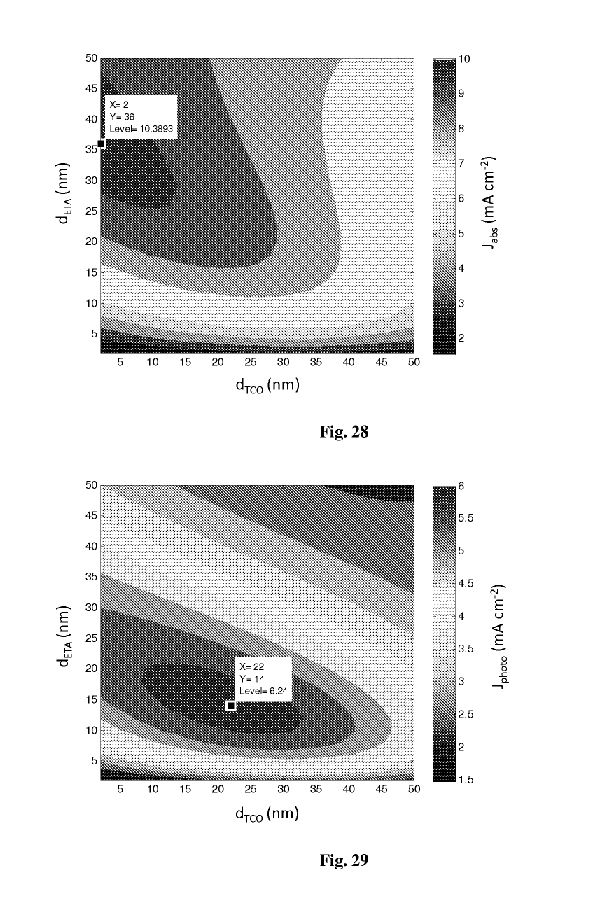

FIGS. 28 and 29 show such calculated results, in terms of the calculated absorbed current density and water photo-oxidation current density, for the V shape with an angle (θ) of 60° between the two photoelectrodes, Ag reflective coating (back reflector), α-Fe₂O₃ photo-absorber layer (ETA) and SnO₂ transparent electrode layer (TCO).

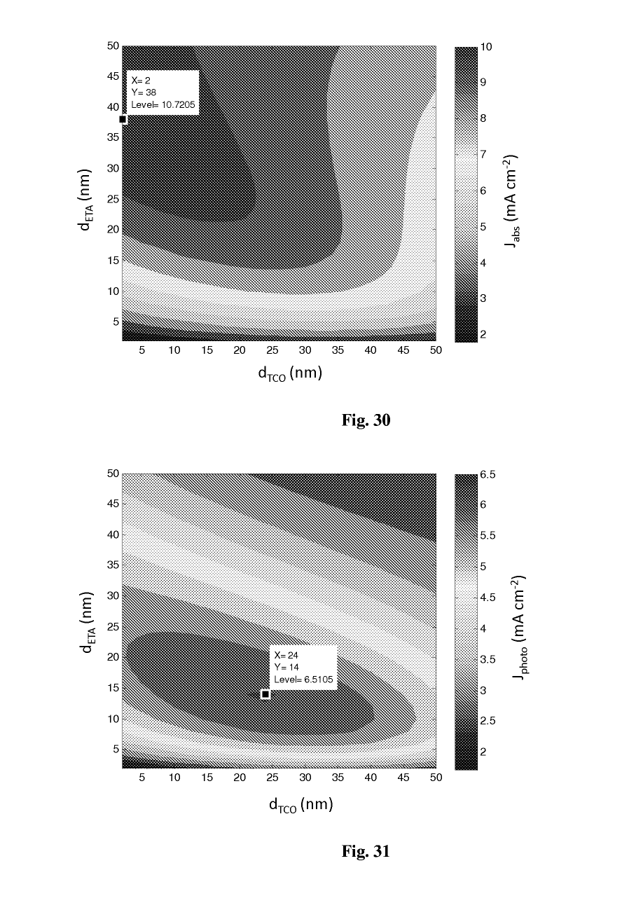

FIGS. 30 and 31 show such calculated results, in terms of the calculated absorbed current density and water photo-oxidation current density, for the V shape with an angle (θ) of 45° between the two photoelectrodes, Ag reflective coating (back reflector), α-Fe₂O₃ photo-absorber layer (ETA) and SnO₂ transparent electrode layer (TCO).

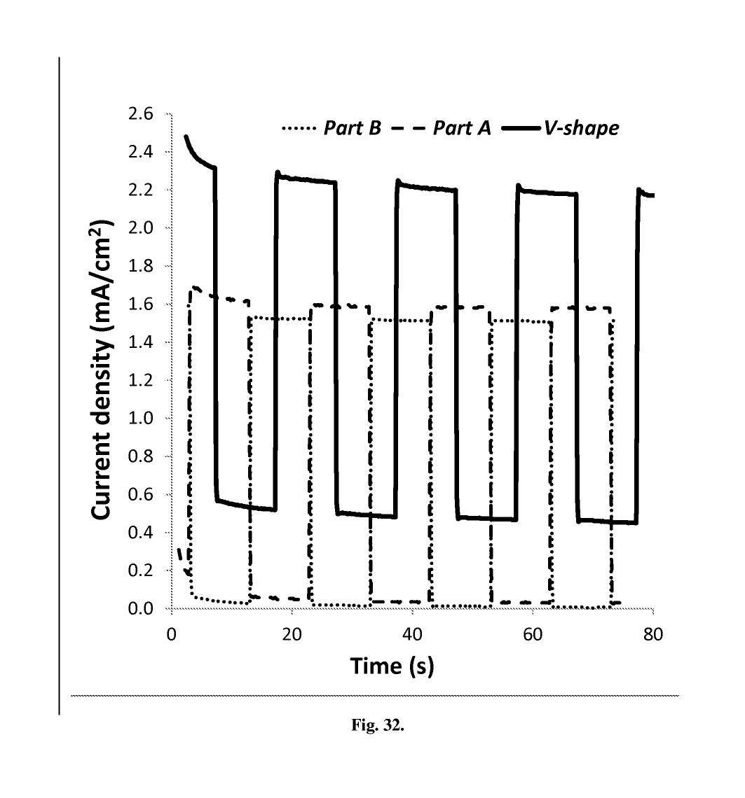

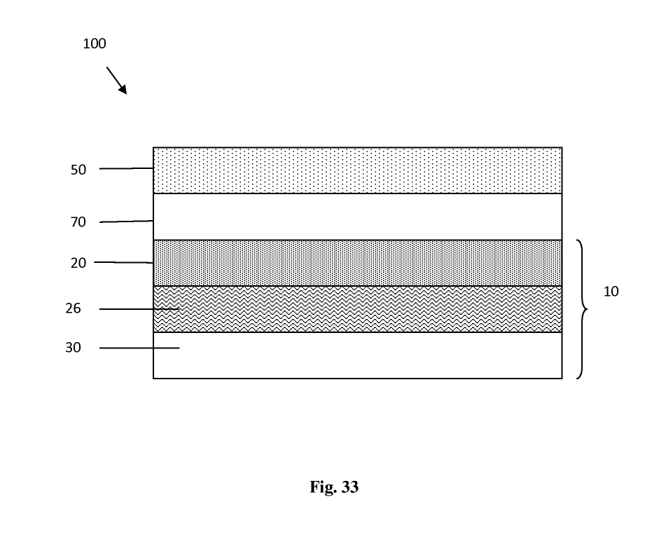

FIG. 32 illustrates experimental photoelectrochemical test of a V shape cell with an angle (θ) of 90° between two similar photoelectrodes, having the same configuration as the one in FIG. 13. The current density is plotted against the time during cyclic exposure to light-on light-off cycles (100 mW cm⁻², white light) while the electrode potential is being set to 1.63 Volts against the RHE scale (V_{RHE}). The measurements were carried out in 1 M NaOH aqueous solution. The “Part A” curve is the current density obtained with direct incident light on one electrode (electrode A), the “Part B” curve is the current density obtained with direct incident light on the second electrode (electrode B), and the “V-shape” curve is the current density with direct incident light on the V-shape cell with electrodes A and B set in 90° to each other.

As indicated above, a hybrid cell unit may be configured such that the PV cell is located downstream with respect to the light collection by the photoelectrode of the present invention. However, as also indicated above the PV cell 50 may be located upstream to another radiation convertor 10, this is shown in FIG. 33 schematically illustrating a tandem cell based device 100 utilizing a semi-transparent PV cell 50 being placed on top of a photoelectrochemical cell 10 (or a second PV cell). The PV cell 50 is configured to absorb a certain spectral range while transmitting a second portion of the incident spectral range to the photoelectrode 10. The two cells absorb different spectral regions of the solar spectrum, and the second cell (the one at the bottom) employs one of the light trapping strategies described in this invention (e.g., the ones illustrated in FIG. 2, 13, 17, 19, 21, or 24). The PV cell 50 may be placed above a container 70 holding aqueous solution, or directly above the photoelectrode unit 10. In the latter case a transparent electrode 26 may be used for charge collection.

Thus, generally, a photoelectrode unit of the present invention for use in a photoelectrochemical cell may be positioned on a base substrate, which in some embodiments may be configured as a photovoltaic cell. A reflective layer (at least partially reflective structure) is deposited on top of the base substrate, and a semiconductor electrode layer is deposited on top of the reflective structure. The reflective structure is configured to reflect light in a wavelength range corresponding to the absorbance band of the semiconductor electrode layer and may be configured to transmit light of different wavelength ranges.

The semiconductor electrode layer of a certain material composition is configured to be of a predetermined thickness in order to provide light trapping within the layer. The thickness of the semiconductor layer is such that light components reflected from the reflective layer and light components impinging onto the electrode layer are of opposite phases and therefore destructively interfere. The thickness of the semiconductor layer actually operates as an anti-reflective coating placed on the reflective layer. The predetermined thickness of the semiconductor layer is chosen according to the calculation methodology described above that satisfy maximal product of absorption of the incident light at the semiconductor electrode layer and charge separation and injection yields.

An additional transparent conducting layer, such as transparent conducting oxide (TCO), may be deposited between the reflective layer and the semiconductor electrode layer in order to reduce back injection of minority charge carriers through the reflective layer. The additional layer may be for example a layer of TiO₂ or F—SnO₂. This transparent layer reduces back injection of charge carriers and thus may increase the efficiency of the photoelectrochemical cell unit. It also reduces the optimal film thickness of the photoelectrode that is necessary to achieve maximal light absorption from quarter wavelength to a fraction of this thickness thereby enabling to enhance the charge collection efficiency without diminishing the light harvesting efficiency.

In some embodiments, two photoelectrochemical cell units are placed together in a “V” shape configuration such that light components reflected from one of the cell units are directed to the other cell unit and thus further improve the efficiency of the photoelectrochemical cell units combined together.

To this end, the following describes a generalized approach for the layer structure design of the present invention. The generalize approach may be used to determine the layer structure for a photoelectrode unit utilizing a photo-absorbing semiconductor layer structure placed on at least partially reflective layer structure and configured for light trapping in an anti-reflective layer structure (i.e. said photo-absorbing structure). The semiconductor layer structure include at least one layer of photo absorbing semiconductor and possibly additional layer(s) which may or may not be electrically conductive, and may include a layer configured to provide stability (to prevent diffusion and corrosion) to the reflective layer structure. The reflective layer structure may be a metallic reflective layer or a stack layer structure configured to be reflective to a certain selected wavelength range (e.g. dielectric mirror, dichroic mirror, etc.) corresponding to the absorption spectrum of the photo absorbing semiconductor.

The improved generation of holes of the described device is a result of constructive interference of the forward and backward propagating fields in the active layer (i.e., the photo-absorber film), at the interface with the hole acceptor (i.e. the intensity at the interface is above the average, or even peaks). Such phases result from the effect of all the layers below the active one. For the simple case of a single active layer on a reflective substrate, the calculation appears on equation 4, and 4A. To expand the calculation to any number of intermediate layers, the general principles of optics can be used by employing the transfer matrix formalism calculations for electric field of light in a stack of parallel layers. In using the transfer matrix method to calculate the electromagnetic field within a stack of thin films, for each point within the stack the field is composed of two complex coefficients, one relating to the forward propagating field and the other to the backward propagating field. Since the calculation is linear with respect to the light field, the two coefficients at one point are related to the coefficients at any other point by a 2×2 matrix. Before going into matrix formalism, the physical principle to form the matrices defines that if the two coefficients are given at a point in the m^{th} layer, the forward and backward fields at distance a from that point will change by e^{ik}^{_{x,m}}^{·a} and e^{-ik}^{_{x,m}}^{·a}, respectively (the forward propagating acquire positive phase at distance a, and the negative acquire negative phase), k_{x,m} is the propagating coefficient defined below. The relation between the two coefficients below and above some interface (e.g. between the m and m+1 layers) is more complicated, but satisfies the continuity relation for the electric and magnetic fields, according to Maxwell's equations. To go into matrix formalism, the following conditions and variables are to be defined:
The light wave vector is \vec{k}=(kₓ,k_{y});
The x-axis propagates into the stack;
The y-axis is parallel to the stack;
Light is assumed to be propagating in a transparent medium ñ₁=n₁ (water, air, etc.), while being incident on the first layer with angle θ;
The complex refraction index of the m^{th} layer is \hat{n}ₘ=nₘ+iκₘ;
According to Snell's law k_{y} is constant in all layers −k_{y,1}=k_{y,2}= . . . =k_{y,N+1} and is given by

$${k}_{y , I} = \frac{2 π}{λ} sin θ \cdot {n}_{I} ,$$

where λ denotes the wavelength in vacuum;
In the m^{th} layer, k_{x,m} is given by

$${k}_{x , m} = \sqrt{{( \frac{2 π}{λ} )}^{2} {\hat{n}}_{m}^{2} - {k}_{y , m}^{2}} ;$$

The stack is composed of N+1 layers, where the last one is either infinite (water, air, bulk glass), or highly reflective (metal/alloy), so in it there is only forward propagating field;
TE and TM are the light polarizations for respectively an incident electric field parallel to the layers, and an incident magnetic field parallel to the layers.

Let us define the coefficients of the forward and backward propagating light waves at the water-photoelectrode surface (inside the photoelectrode) as A₁,B₁, respectively. At any point in the photoelectrode at distance x from the water-photoelectrode interface, the fields will be A₁e^{ik}^{₁}^{^{x}}^{x}, Bᵢe^{-ik}^{₁}^{^{x}}^{x}, so their change can be described by matrix form

$$( \begin{matrix}A ( x ) \\ B ( x )\end{matrix} ) = ( \begin{matrix}{e}^{i {k}_{x , 1} x} & 0 \\ 0 & {e}^{- i {k}_{x , 1} x}\end{matrix} ) ( \begin{matrix}{A}_{1} \\ {B}_{1}\end{matrix} ) = {M}^{prop} ( \begin{matrix}{A}_{1} \\ {B}_{1}\end{matrix} )$$

At the interface between layer 1 and layer 2, the fields obey the continuity demand raised by Maxwell's equations. The field's coefficients right before the interface A₁,B₁, and right after the interface A₂,B₂ are connected by relation:

$$( \begin{matrix}{A}_{2} \\ {B}_{2}\end{matrix} ) = {M}_{1 \to 2} ( \begin{matrix}{A}_{1} \\ {B}_{1}\end{matrix} )$$

The relation M_{1→2} between these coefficients for the different polarizations is the result of imposing Maxwell's laws on the interface and is given as:

$$\begin{matrix}{M}_{1 \to 2}^{TE} = \frac{1}{2} ( \begin{matrix}( 1 + {q}_{TE} ) & ( 1 - {q}_{TE} ) \\ ( 1 - {q}_{TE} ) & ( 1 + {q}_{TE} )\end{matrix} ) & where {q}_{TE} = \frac{{k}_{x , 1}}{{k}_{x , 2}} \\ {M}_{1 \to 2}^{TM} = \frac{1}{2} \frac{{\hat{n}}_{1}}{{\hat{n}}_{2}} ( \begin{matrix}( 1 + {q}_{TM} ) & ( {q}_{TM} - 1 ) \\ ( {q}_{TM} - 1 ) & ( 1 + {q}_{TM} )\end{matrix} ) & where {q}_{TM} = {( \frac{{\hat{n}}_{2}}{{\hat{n}}_{1}} )}^{2} \frac{{k}_{x , 1}}{{k}_{x , 2}}\end{matrix}$$

As a generalization, the matrix can be defined taking into account the propagation through layer m of thickness dₘ.

$${M}_{m}^{prop} = ( \begin{matrix}{e}^{i {k}_{x , m} {d}_{m}} & 0 \\ 0 & {e}^{- i {k}_{x , m} {d}_{m}}\end{matrix} )$$

and the interface matrix can be defined by taking the coefficients from the end of layer m to the beginning of layer m+1

$$\begin{matrix}{M}_{m \to m + 1}^{TE} = \frac{1}{2} ( \begin{matrix}( 1 + {q}_{TE} ) & ( 1 - {q}_{TE} ) \\ ( 1 - {q}_{TE} ) & ( 1 + {q}_{TE} )\end{matrix} ) & where {q}_{TE} = \frac{{k}_{x , 1}}{{k}_{x , 2}} \\ {M}_{m \to m + 1}^{TM} = \frac{1}{2} \frac{{\hat{n}}_{1}}{{\hat{n}}_{2}} ( \begin{matrix}( 1 + {q}_{TM} ) & ( {q}_{TM} - 1 ) \\ ( {q}_{TM} - 1 ) & ( 1 + {q}_{TM} )\end{matrix} ) & where {q}_{TM} = {( \frac{{\hat{n}}_{2}}{{\hat{n}}_{1}} )}^{2} \frac{{k}_{x , 1}}{{k}_{x , 2}}\end{matrix}$$

Therefore, the relation between A₁,B₁ of the TE polarization (TM polarization is done in the same way) and the coefficients at the beginning of layer N+1 (and last) layer, A_{N+1},B_{N+1} is given by matrix multiplication

$$( \begin{matrix}{A}_{N + 1} \\ {B}_{N + 1}\end{matrix} ) = \underbrace{{M}_{N \to N + 1}^{TE} {M}_{N}^{prop} … {M}_{2 \to 3}^{TE} {M}_{2}^{prop} {M}_{1 \to 2}^{TE} {M}_{1}^{prop}}_{{M}_{total}} ( \begin{matrix}{A}_{1} \\ {B}_{1}\end{matrix} )$$

The reason the last layer is considered is because it provides a constraint. In the present example, no backward field exists at the N+1 layer meaning that B_{N+1}=0 B_{N+1}=0 (there is no light coming from within the metal toward the interface. The same condition applies to thick layers). Therefore, by defining

$${M}_{total} = ( \begin{matrix}a & b \\ c & d\end{matrix} )$$

we get the equation

$$( \begin{matrix}{A}_{N + 1} \\ 0\end{matrix} ) = ( \begin{matrix}a & b \\ c & d\end{matrix} ) ( \begin{matrix}{A}_{1} \\ {B}_{1}\end{matrix} )$$

and specifically, the relation between A₁,B₁ to be

$${cA}_{1} + {dB}_{1} = 0 ⇒ \frac{{B}_{1}}{{A}_{1}} = - \frac{d}{c} .$$

A few aspects arise from calculating the coefficients of the forward and backward fields, as follows. The phase difference between the forward and backward propagation is solely a function of the wavelength, and the structure of layers. For constructive interference at the interface, the following condition should be satisfied:

$$arg [ \frac{{B}_{1}}{{A}_{1}} ] = 0$$

with A₁(B₁) being the coefficient for the forward (backward) field at the photoelectrode-water interface (inside the photoelectrode).

A closed form solution for this condition can be calculated by using the weighted-average wavelength λ̅ (Eq. 1), however, since multiple wavelengths play a role, as well as considerations regarding the amount of over-all absorption and the probability of the charge carriers to reach the surface, the above condition can be phrased with some flexibility as

$$arg [ \frac{{B}_{1}}{{A}_{1}} ] = ɛ ,$$

where ∈ incorporates these considerations. To ensure constructive interference, s should be in the range of

$$- \frac{1}{2} π < ɛ < \frac{1}{2} π$$

for λ̅.

For constructive interference somewhere within the active layer (suppose at depth x), to balance other physical processes as multiple wavelengths, charge carrier mean free path, etc., the condition is

$$arg [ \frac{{B}_{1} {e}^{- i {k}_{x , 1} x}}{{A}_{1} {e}^{i {k}_{x , 1} x}} ] = ɛ .$$

In order to find the absolute value of A₁, B₁, the same principle can be used to find the coefficient of the propagating light before it enters the stack. In other words, the solar spectrum determines the size of A₁, B₁, and the stack determines their relative phase.

Using the matrix formalism allows for calculating the field at any depth in any of the layers of the stack for any given wavelength. To calculate the actual charge generated by the absorbed photons one needs to acquire the electric field (as a vector) for each polarization, per unit wavelength of the solar spectrum, and to find the photons absorption profile. The overall photon absorption is an integral over the contribution of the entire solar spectrum, for both polarizations. Equation 6 above describes this integration for light incident at an angle θ=0.

Besides carrier generation by light absorption, one needs to estimate also the probability of the photo-generated minority carriers to contribute to the photocurrent. The following presents these calculation steps:

1. Vector electric field:
i. For TE polarization (electric field parallel to the layers), the electric field is:

\vec{E}^{TE}(x)=\tilde{z}(A₁^{TE}e^{ik}^{_{x,1}}^{x}+B₁^{TE}e^{ik}^{_{x,1}}^{x})

|\vec{E}^{TE}(x)|² is hence |A₁^{TE}e^{ik}^{_{x,1}}^{x}+B₁^{TE}e^{ik}^{_{x,1}}^{x}|².
ii. For TM polarization (Magnetic field parallel to the layers) the electric fields that propagate forward and backward are not parallel, so the vector electric field depends on the angle and is:

\vec{E}^{TM}(x)=A₁^{TM}e^{ik}^{_{x,1}}^{x}(sin θ\hat{x}−cos θŷ)+B₁^{TM}e^{ik}^{_{x,1}}^{x}(−sin θ\hat{x}−cos θŷ)

|\vec{E}^{TM}(x)|² is therefore |\vec{E}^{TM}(x)|²=|Eₛᵢₙ|²+|E_{cos}|², where

Eₛᵢₙ=|sin θ|·(A₁^{TM}e^{ik}^{_{x,1}}^{x}+B₁^{TM}e^{ik}^{_{x,1}}^{x}), E_{cos}=|cos θ|·(A₁^{TM}e^{ik}^{_{x,1}}^{x}−B₁^{TM}e^{ik}^{_{x,1}}^{x})

2. The energy absorption rate is

$$\frac{λ}{π} m [ {k}_{1 , x} ] e [ {k}_{1 , x} ] \cdot ( {\vert {\vec{E}}^{TM} ( x ) \vert}^{2} + {\vert {\vec{E}}^{TE} ( x ) \vert}^{2} ) ,$$

and the photon absorption rate is

$$a ( λ , x ) = \frac{λ}{π} m [ {k}_{1 , x} ] e [ {k}_{1 , x} ] \cdot ( {\vert {\vec{E}}^{TM} ( x ) \vert}^{2} + {\vert {\vec{E}}^{TE} ( x ) \vert}^{2} ) \cdot {( \frac{hc}{λ} )}^{- 1} ,$$

where kₓ is the part of the complex wave vector that is perpendicular to the layer interface, and λ is the wavelength in vacuum.

3. The photon absorption as a function of depth within the active layer, and hence generation is the contribution of each λ and each polarization:

$$g ( x ) = {\sum }_{polarizations} {\int }_{{λ}_{min}}^{{λ}_{max}} {I}_{λ}^{0} ( λ ) a ( λ , x ) d λ$$

Here I_{λ}⁰(λ) is the number of photons per unit wavelength around λ incident at the surface of the photo-absorber film (i.e., at x=0), and g(x) is the resulted electron-hole generation distribution. The contribution of the generated charge is shown in equations 6 and 8.

As indicated above, the photoelectrochemical cell unit may be combined with a photovoltaic cell unit in order to provide potential bias to the photoelectrochemical cell unit. The photovoltaic cell can be configured as the substrate on which the photoelectrochemical cell unit is deposited, or separated and electrically connected thereto. According to some embodiments, the photovoltaic cell is a standard commercially available photovoltaic cell. A partially reflective layer, such as a dichroic of dielectric mirror, configured to reflect light in wavelengths absorbed by the semiconductor electrode layer and to transmit light at wavelengths absorbed by the photovoltaic cell is deposited on top of the photovoltaic cell and the semiconductor layer is deposited on top of the partially reflective layer. The combined hybrid cell is configured such that a certain wavelength range is reflected from the partially reflective layer and trapped within the semiconductor layer to be absorbed thereof, while a certain other wavelength range is transmitted through the partially reflective layer and absorbed in the photovoltaic cell to thereby provide bias voltage to the electrochemical cell unit for the electrochemical process.

1. A radiation conversion device comprising:
at least one radiation conversion cell, the at least one radiation conversion cell comprising:
a photo-absorber unit having a predetermined absorption spectrum for absorbing radiation of a certain wavelength range thereby converting the absorbed radiation into charge carriers, and
at least partially reflective layer structure configured to be substantially reflective for said certain wavelength range, the photo-absorber unit and the at least partially reflective layer structure being configured to provide a desired refractive index profile across the at least one radiation conversion cell with respect to said certain wavelength range and to define an optical cavity with respect to said certain wavelength range within the photo-absorber unit, thereby providing a desired interference condition for said certain wavelength range, thereby causing the radiation, absorbed by and propagating through said photo-absorber unit while being reflected from said at least partially reflective layer structure, to be effectively trapped within said photo-absorber unit.

2. The device of claim 1, wherein the photo-absorber unit comprises an optically active semiconductor structure having a predetermined material composition and thickness being selected to operate as an anti-reflective structure for said certain wavelength range corresponding to maximal absorption of incident electromagnetic radiation by said optically active semiconductor structure.

3. The radiation conversion device of claim 1, wherein said at least partially reflective layer structure is a single- or multi-layer structure.

4. The radiation conversion device of claim 1, wherein said at least partially reflective layer structure is configured as a wavelength-selective reflector.

5. The radiation conversion device of claim 2, wherein said photo-absorber unit comprises the optically active semiconductor structure and an electrode structure which is substantially transparent for said certain wavelength range, said electrode structure interfacing said at least partially reflective layer structure on one side thereof and said optically active semiconductor structure at an opposite side thereof.

6. The radiation conversion device of claim 2, wherein said photo-absorber unit has a thickness selected to be about λ̅/4n, where λ̅ is a weighted average wavelength of said certain wavelength range and n is an effective refractive index of said optically active semiconductor structure.

7. The radiation conversion device of claim 2, wherein said photo-absorber unit has a thickness smaller than a recombination length for photo-generated charge carriers in said optically active semiconductor structure.

8. The radiation conversion device of claim 1, wherein said at least partially reflective layer structure is a dielectric or dichroic mirror structure.

9. The radiation conversion device of claim 1, wherein said at least partially reflective layer structure comprises a substrate having an at least partially reflective coating comprising one of the following material compositions: silver-gold or silver-platinum alloys.

10. The radiation conversion device of claim 2, wherein said optically active semiconductor structure comprises an α-Fe₂O₃ layer.

11. The radiation conversion device of claim 10, wherein said at least partially reflective layer structure comprises a substrate having an at least partially reflective coating comprising one of the following material compositions: silver-gold composition with 5% to 15% gold; or silver-platinum alloys with 10% to 22% platinum.

12. The radiation conversion device of any one of claim 1, configured as a photoelectrochemical device.

13. The radiation conversion device of claim 12, configured for photoelectrolysis of water.

14. The radiation conversion device of claim 1, comprising at least two radiation conversion cells configured to face one another by their radiation absorbing layers with a certain angle to allow incident electromagnetic radiation reflected from one of the cells to propagate towards and be absorbed by the other cell.

15. The radiation conversion device of claim 14, wherein said at least two radiation conversion cells are arranged in a V shape configuration, said certain angle ranging between 30 and 90 degrees.

16. The radiation conversion device of claim 1, further comprising a photovoltaic cell located below said at least partially reflective layer structure, said at least partially reflective layer structure being configured to reflect light component of said certain wavelength range while transmitting light components with a different wavelength range corresponding the absorption spectrum of said photovoltaic cell.

17. The radiation conversion device of claim 1, further comprising a partially transparent photovoltaic cell located on top of said photo-absorber unit, said partially transparent photovoltaic cell is configured to transmit light components of said certain wavelength range while absorbing a different wavelength range.

18. A method for forming a radiation conversion device, the method comprising:
applying an at least partially reflective coating layer structure on a substrate; and
applying a photo-absorber structure comprising an optically active semiconductor of a predetermined thickness and a predetermined absorption spectrum on top of said at least partially reflective coating layer, said predetermined thickness being selected in accordance with refractive index profile along the radiation conversion device to thereby provide an optical cavity providing a desired interference condition for said certain wavelength range within said photo-absorber structure thereby causing light of a wavelength range within said predetermined absorption spectrum impinging onto said photo-absorber structure to be trapped within said optically active semiconductor.

19. The radiation conversion device of claim 1, wherein said photo-absorber unit is directly interfaced with said at least partially reflective layer structure.

20. A radiation conversion device, comprising:
at least one radiation conversion cell, the at least one radiation conversion cell comprising:
a photo-absorber unit configured as a thin film structure having a predetermined absorption spectrum for absorbing radiation of a certain wavelength range thereby converting the absorbed radiation into charge carriers, said thin film structure having a light collecting surface, and
at least partially reflective layer structure configured to be substantially reflective for said certain wavelength range, said at least partially reflective layer structure interfacing with a surface of said thin film structure opposite to said light collecting surface,
wherein the thin film photo-absorber unit has a predetermined material composition and thickness selected such that the photo-absorber unit and the at least partially reflective layer structure provide a desired refractive index profile across the at least one radiation conversion cell with respect to said certain wavelength range and form a resonance cavity, thereby providing a desired interference condition for said certain wavelength range, causing the radiation, absorbed by and propagating through said photo-absorber unit while being reflected from said at least partially reflective structure, to be effectively trapped within said photo-absorber unit.
